(19) United States
(12) Patent Application Publication
(10) Pub. No.: US 2025/0357258 A1
(43) Pub. Date: Nov. 20, 2025

(54) ELECTRONIC APPARATUS, SEMICONDUCTOR PACKAGE MODULE AND MANUFACTURING METHOD THEREOF

(71) Applicant: Taiwan Semiconductor Manufacturing Company, Ltd., Hsinchu (TW)

(72) Inventors: Wensen Hung, Hsinchu County (TW); Tsung-Yu Chen, Hsinchu City (TW); Jia-Syuan Li, Taoyuan City (TW); Chen-Hsiang Lao, New Taipei City (TW); Hung-Chi Li, Taipei City (TW)

(73) Assignee: Taiwan Semiconductor Manufacturing Company, Ltd., Hsinchu (TW)

(21) Appl. No.: 19/286,119

(22) Filed: Jul. 30, 2025

Related U.S. Application Data
(62) Division of application No. 17/721,345, filed on Apr. 14, 2022.
(60) Provisional application No. 63/242,469, filed on Sep. 9, 2021.

(51) Int. Cl. H01L 23/40; H01L 23/367; H01L 23/427; H01L 23/44; H01L 23/498; H01L 25/065

(52) U.S. Cl. CPC H01L 23/4006; H01L 23/3675; H01L 23/427; H01L 25/0652; H01L 2023/4068; H01L 2023/4087; H01L 23/44; H01L 23/49833

(57) ABSTRACT

An electronic apparatus, a semiconductor package module and a method for manufacturing the semiconductor package module are provided. The semiconductor package module includes: an encapsulated structure, including a device die and an encapsulant laterally enclosing the device die; a package substrate, attached to a first side of the encapsulated structure; a composite thermal interfacial structure, disposed on a second side of the encapsulated structure, and including thermally conductive elements arranged side by side or stacked along a vertical direction; a ring structure, attached to the package substrate and laterally surrounding the encapsulated structure; and a heat spreader, attached to the second side of the encapsulated structure through the composite thermal interfacial structure, and supported by the ring structure.

### CROSS-REFERENCE TO RELATED APPLICATION

This application is a divisional application of and claims the priority benefit of a prior application Ser. No. 17/721,345, filed on Apr. 14, 2022. The prior application Ser. No. 17/721,345 claims the priority benefit of U.S. provisional application Ser. No. 63/242,469, filed on Sep. 9, 2021. The entirety of each of the above-mentioned patent applications is hereby incorporated by reference herein and made a part of this specification.

### BACKGROUND

As the need for electronic devices to process larger amount of data at high speed grows, significant challenges are posed in design and packaging of these devices. In particular, power consumption of those electronic devices with high computational ability is immense, and the electrical power provided to these electronic devices may turn into a great amount of thermal energy. In order to prevent malfunction of the electronic devices resulted from overheating, an effective manner for dissipating heat from these electronic devices is important in the art.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic plan view illustrating an electronic system according to some embodiments of the present disclosure.

FIG. 1B is a schematic cross-sectional view illustrating an electronic device including a plurality of the electronic systems and an immersion cooling apparatus, according to some embodiments of the present disclosure.

FIG. 1C is a schematic cross-sectional view illustrating one of the semiconductor package modules in the electronic system, according to some embodiments of the present disclosure.

FIG. 2A through FIG. 2E are schematic cross-sectional views illustrating intermediate structures at various stages during a manufacturing process for forming the semiconductor package module as shown in FIG. 1C, according to some embodiments of the present disclosure.

FIG. 3 is a schematic cross-sectional view illustrating a semiconductor package module, according to some embodiments of the present disclosure.

FIG. 4A through FIG. 4C are schematic cross-sectional views illustrating intermediate structures at various stages during a manufacturing process for forming the semiconductor package module as shown in FIG. 3, according to some embodiments of the present disclosure.

FIG. 5 is a schematic cross-sectional view illustrating a semiconductor package module, according to some embodiments of the present disclosure.

FIG. 6 is a schematic cross-sectional view illustrating a semiconductor package module, according to some embodiments of the present disclosure.

FIG. 7A through FIG. 7D are schematic cross-sectional views illustrating intermediate structures at various stages during a manufacturing process for forming the semiconductor package module as shown in FIG. 6, according to some embodiments of the present disclosure.

FIG. 8A and FIG. 8B are schematic cross-sectional views illustrating intermediate structures at various stages during a manufacturing process for forming pillar structures as shown in FIG. 6, according to some embodiments of the present disclosure.

FIG. 9 through FIG. 29 are schematic cross-sectional views illustrating semiconductor package modules, according to various embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

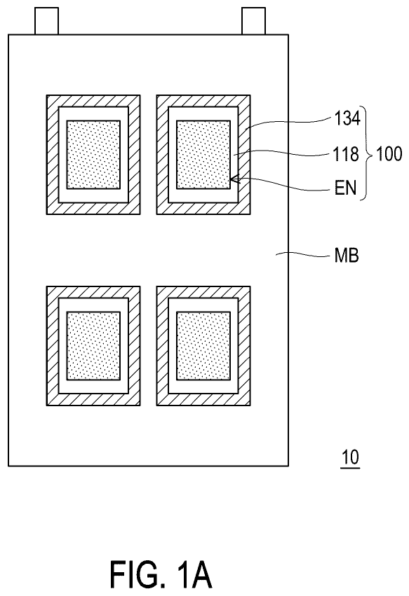

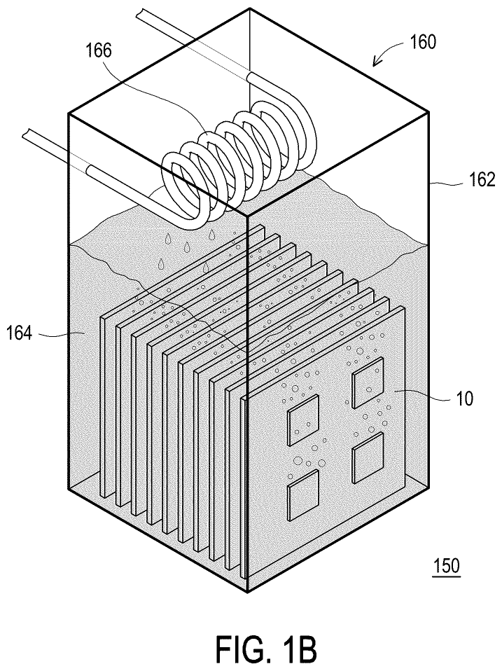

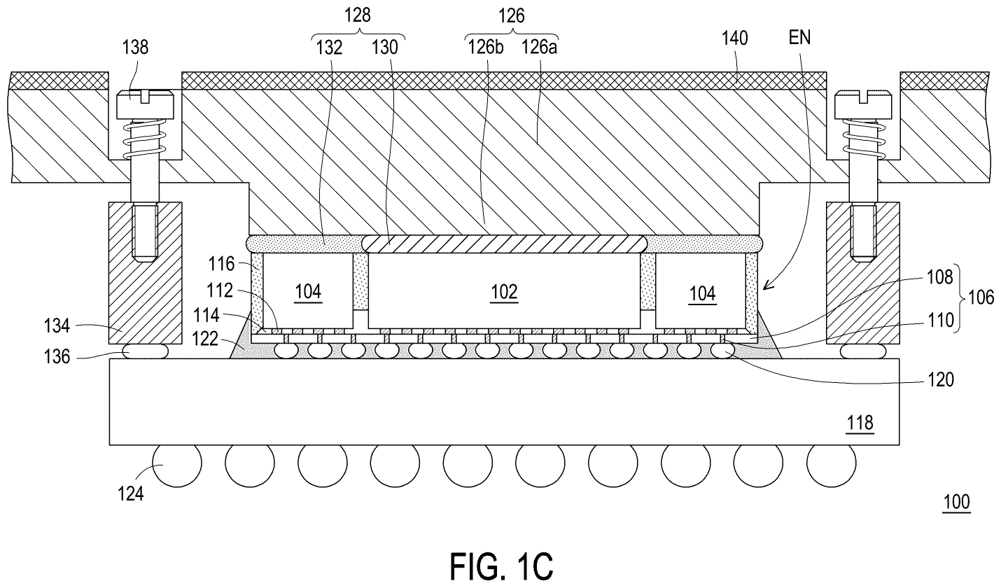

FIG. 1A is a schematic plan view illustrating an electronic system 10 according to some embodiments of the present disclosure.

Referring to FIG. 1A, the electronic system 10 includes multiple semiconductor package modules 100. In some embodiments, the semiconductor package modules 100 are attached to a printed circuit board MB. In alternative embodiments, the semiconductor package modules 100 are respectively attached to an additional printed circuit board (not shown), and these additional circuit boards are fastened to the main printed circuit board MB. Although not shown, the printed circuit board MB may be further mounted with other electronic components. Further, an amount of the semiconductor package modules 100 in the electronic system 10 can be adjusted. As an example, the electronic system 10 is a data server.

FIG. 1B is a schematic cross-sectional view illustrating an electronic apparatus 150 including a plurality of the electronic systems 10 and an immersion cooling apparatus 160, according to some embodiments of the present disclosure.

Referring to FIG. 1B, the immersion cooling apparatus 160 includes a tank 162 for accommodating the electronic systems 10. Although not shown, the electronic systems 10 may be respectively inserted into a slot at a bottom surface of the tank 162, such that the electronic systems 10 may stand in parallel with one another in the tank 162. Further, the tank 162 is filled with a dielectric cooling liquid 164. The electronic systems 10 may be submerged in a bath of the dielectric cooling liquid 164, and thermal energy generated by the electronic systems 10 can be dissipated through the dielectric cooling liquid 164. Since the dielectric cooling liquid 164 is not electrically conductive, shorting between the electronic systems 10 may be avoided. In some embodiments, the immersion cooling apparatus 160 is a two-phase immersion cooling apparatus. In these embodiments, the dielectric cooling liquid 164 is selected as having a low boiling point (e.g., about 50° C.), and the dielectric cooling liquid 164 boils on surfaces of heat generating components. The rising vapors transfer heat out of the dielectric cooling liquid 164, thus heat can be removed from the electronic systems 10. In some embodiments, a condenser 166 (e.g., a coil condenser) is disposed over the bath of the dielectric cooling liquid 164 in the tank 162, and the vapor is cooled at the condenser 166, then returns to the bath of the dielectric cooling liquid 164.

In alternative embodiments, the immersion cooling apparatus 160 is a single-phase immersion cooling apparatus 160. In these alternative embodiments, the dielectric cooling liquid 164 may have a higher boiling point, and may not undergo a low temperature vaporization process at the surfaces of the heat generating components. Further, the condenser 166 may be omitted, and the dielectric cooling liquid 164 may be directed to a heat exchanging unit (not shown) outside the tank 162. The dielectric cooling liquid 164 being heated in the tank 162 may be cooled down at the heat exchanging unit, then circled back to the tank 162.

However, the electronic systems 10 is not limited to be equipped with the immersion cooling apparatus 160 as described above. Those skilled in the art may select a proper cooling apparatus for the electronic systems 10, as long as the heat generated from the electronic systems 10 can be effective removed by the cooling apparatus. In addition to external heat dissipation path, heat dissipation path in each electronic system 10 significantly affects heat dissipation efficiency of the electronic system 10.

FIG. 1C is a schematic cross-sectional view illustrating one of the semiconductor package modules 100 in the electronic system 10, according to some embodiments of the present disclosure.

Referring to FIG. 1A and FIG. 1C, the semiconductor package module 100 may include multiple device dies. For instance, the semiconductor package module 100 may include a device die 102 and die stacks 104 aside the device die 102. The device die 102 may be a system-on-chip (SOC) device die, and each of the die stacks 104 may include a stack of memory dies (not shown). The device die 102 and the die stacks 104 may be arranged side by side, and are laterally separated with one another. In some embodiments, the device die 102 and the die stacks 104 are attached to an interposer 106. The interposer 106 may include a semiconductor substrate 108 (e.g., a silicon substrate) and through substrate vias (TSV) 110 penetrating through the semiconductor substrate 108. The TSVs 110 are electrically connected to the device die 102 and the die stacks 104, and establish conduction paths extending between opposite sides of the semiconductor substrate 108. Although not shown, the interposer 106 may further include metallization layers at one or both sides of the semiconductor substrate 108, and the TSVs 110 may be connected to one or both sides of the interposer 106 through interconnection elements (e.g., a combination of conductive lines and conductive vias) in the metallization layers.

In alternative embodiments, the interposer 106 may include a stack of polymer layers and interconnection elements spreading in the stack of polymer layers. In other embodiments, the interposer 106 may include a molding compound substrate with vias penetrating through, and may further include metallization layers at one or both sides of the molding compound substrate. Interconnection elements (e.g., a combination of conductive lines and conductive vias) in the metallization layers may be electronically connected to the vias extending through the molding compound substrate.

The device die 102 and the die stacks 104 may be attached to the interposer 106 via electrical connectors 112. As an example, the electrical connectors 112 may be micro-bumps. In some embodiments, the electrical connectors 112 are laterally surrounded by an underfill 114 spreading in a space between the interposer 106 and the attached device die 102 and die stacks 104. Further, in some embodiments, the device die 102 and the die stacks 104 are laterally encapsulated by an encapsulant 116. A surface of the encapsulant 116 may be coplanar with surfaces of the device die 102 and the die stacks 104 that are facing away from the interposer 106.

Further, in some embodiments, the interposer 106 attached with the device die 102 and the die stacks 104 may be further attached to a package substrate 118, along with other electronic components (not shown, such as passive devices). In some embodiments, although not shown, the package substrate 118 includes a dielectric core layer and build-up layers at one or both sides of the dielectric core layer, and conductive wirings may spread in the build-up layers. In alternative embodiments, the package substrate 118 is a core-less substrate, and includes a stack of build-up layers and conductive wirings spreading in the stack of build-up layers. Signals from the device die 102 and the die stacks 104 can be routed to another side of the package substrate 118 through the conductive wirings in the package substrate 118. In some embodiments, the interposer 106 is attached to the package substrate 118 through electrical connectors 120. As an example, the electrical connectors 120 may be controlled collapsed chip connection (C4) bumps. In some embodiments, electrical connectors 120 are laterally surrounded by an underfill 122 spreading in a space between the interposer 106 and the package substrate 118. Moreover, in some embodiments, electrical connectors 124 are disposed at a side of the package substrate 118 facing away from the interposer 106, and may be functioned as inputs/outputs (I/Os) of the semiconductor package module 100. As an example, the electrical connectors 124 may be ball grid array (BGA) balls.

In order to effectively remove heat from the device die 102 and the die stacks 104, a heat spreader 126 may be attached to an encapsulated structure EN including the device die 102, the die stacks 104 and the encapsulant 116. The heat spreader 126 may be formed of a conductive material, such as metal or metal alloy. As an example, the heat spreader 126 may be formed of a material with high thermal conductivity such as copper, aluminum, cobalt, copper coated with nickel, stainless steel, tungsten, copper-tungsten, copper-molybdenum, silver diamond, copper diamond, aluminum nitride, aluminum silicon carbide, the like or combinations thereof. In some embodiments, the conductive material is further coated with another metal, such as gold, nickel, titanium gold alloy, lead, tin, nickel vanadium or the like. In some embodiments, the heat spreader 126 has a plate portion 126a and an engaging portion 126b. The plate portion 126a laterally spans over the encapsulated structure EN. The engaging portion 126b extends downwardly from the plate portion 126a, to attach with the encapsulated structure EN. The engaging portion 126b of the heat spreader 126 is attached to back sides of the device die 102 and top dies of the die stacks 104, which are facing away from the interposer 106. Active devices may be formed at front sides of the device die 102 and the dies in the die stacks 104, and the back sides are opposite to the front sides. In some embodiments, the engaging portion 126b of the heat spreader 126 entirely covers the encapsulated structure EN. In these embodiments, the device die 102, the die stacks 104 and the encapsulant 116 in the encapsulated structure EN are entirely overlapped with the engaging portion 126b of the heat spreader 126.

In some embodiments, the engaging portion 126b of the heat spreader 126 is attached to the encapsulated structure EN through a composite thermal interfacial layer 128. The composite interfacial layer 128 can facilitate adhesion between the heat spreader 126 and the encapsulated structure EN. The composite thermal interfacial layer 128 may include a metallic layer 130 and a gel thermal interfacial material (TIM) 132 laterally enclosing the metallic layer 130. The metallic layer 130 has a superior thermal conductivity (e.g., 3 W/(mK) to 150 W/(mK)), and may be in direct contact with hot sources in the encapsulated structure EN (e.g., the device die 102). In some embodiments, the metallic layer 130 may be formed of a metal or a metal alloy having low melting point. For instance, the metallic layer 130 may be formed of indium, copper, bismuth gallium, rhodium, the like or combinations thereof, and may have a melting temperature ranging from 60° C. to 120° C. In these embodiments, the metallic layer 130 may be provided on the encapsulated structure EN as a metal foil during manufacturing, and may be melted into a molten state while receiving heat from the device die 102 and the die stacks 104 during operation of the device die 102 and the die stacks 104. Alternatively, the metallic layer 130 may be formed of a metal or a metal alloy maintaining liquid state at room temperature. For instance, the metallic layer 130 as liquid metal may be formed of gallium based alloy, indium based alloy, indium tin based alloy, or the like. In these alternative embodiments, the metallic layer 130 may be provided on the encapsulated structure EN as fluid.

The gel TIM 132 laterally enclosing the metallic layer 130 may prevent the metallic layer 130 in molten state from escaping out of the space between the engaging portion 126b of the heat spreader 126 and the encapsulated structure EN. The gel TIM 132 may include a crosslinkable silicone polymer (e.g., vinyl-terminated silicone polymer), a crosslinker and thermally conductive fillers. Applicable thermal conductive filler materials may include aluminum oxide, boron nitride, aluminum nitride, aluminum, copper, silver, indium, the like or combinations thereof.

In some embodiments, the plate portion 126a of the heat spreader 126 laterally extending over the engaging portion 126b is fastened to a ring structure 134 disposed on the package substrate 118. The encapsulated structure EN including the device die 102 and the die stacks 104 is laterally surrounded by the ring structure 134. As an example, the ring structure 134 may be formed of a metallic material, but the present disclosure is not limited thereto. For instance, the ring structure 134 may be formed of one of the material candidates for forming the heat spreader 126. In some embodiments, the ring structure 134 is attached to the package substrate 118 through an adhesive 136. Further, in some embodiments, the plate portion 126a of the heat spreader 126 is fastened to the ring structure 134 by screws 138, such as spring loaded screws. In these embodiments, the plate portion 126a of the heat spreader 126 may have screw holes aligned with screw holes in the ring structures 134, respectively.

Moreover, in those embodiments where the semiconductor package modules 100 are designed to be compatible with a two-phase immersion cooling apparatus (e.g., the immersion cooling apparatus 160 as shown in FIG. 1B), the heat spreader 126 may be coated with one or multiple layers of wicking structure 140. The wicking structure 140 may improve capillary performance at surface of the heat spreader 126. Further, the wicking structure 140 may include a porous layer or include microstructures (e.g., mesh, bumps etc.), thus may promote nucleate boiling by increasing nucleation site density. Therefore, the layer(s) of wicking structure 140 may also be referred as a boiling enhancement coating (BEC) layer. As an example, the wicking structure 140 may include a microporous sintered metal powder coating layer, such as a microporous copper powder coating layer. In some embodiments, the wicking structure 140 is formed at a side of the heat spreader 126 facing away from the semiconductor package modules 100. In other embodiments, all of the surfaces of the heat spreader 126 in contact with the dielectric cooling liquid 164 (as shown in FIG. 1B) are coated with the wicking structure 140.

As described above, the heat spreader 126 is directly attached to the encapsulated structure EN through the composite thermal interfacial layer 128 without an additional heat spreader and an additional thermal interfacial layer in between. In this way, heat generated from the encapsulated structure EN can be conducted to the heat spreader 126 along a shorter path, and a high thermal resistance component (e.g., the additional thermal interfacial layer formed of grease TIM) would not stand in between the encapsulated structure EN and the heat spreader 126. Therefore, efficiency of heat dissipation inside the semiconductor package module 100 can be effectively improved. Furthermore, as having the metallic layer 130 with superior thermal conductivity, the composite thermal interfacial layer 128 may have a reduced thermal resistance, as compared to a grease TIM layer or a gel TIM layer. As removal of the additional heat spreader and the additional thermal interfacial layer, the heat spreader 126 may be attached to the package substrate 120 by being fastened to the ring structure 134 disposed on the package substrate 120 and laterally surrounding the encapsulated structure EN.

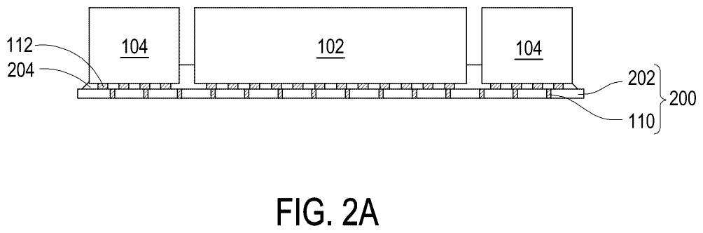

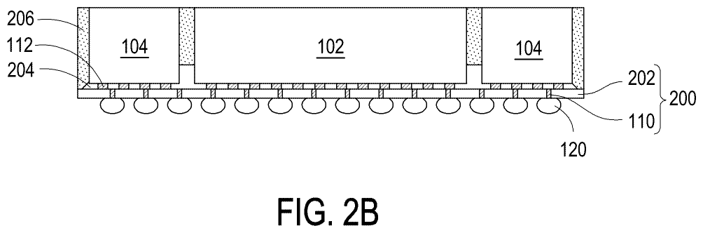

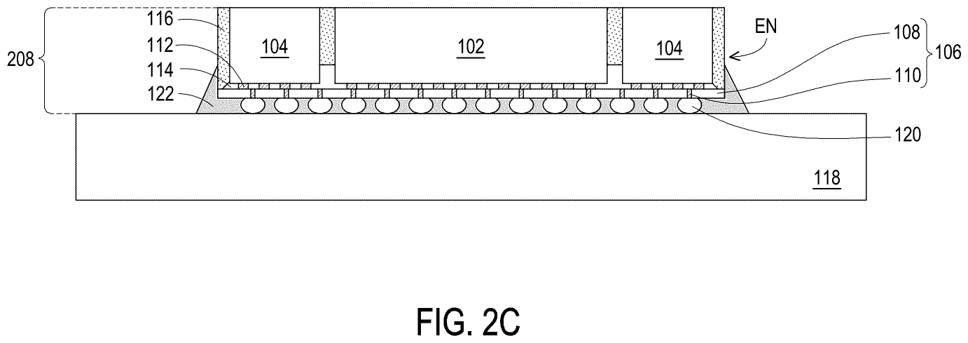

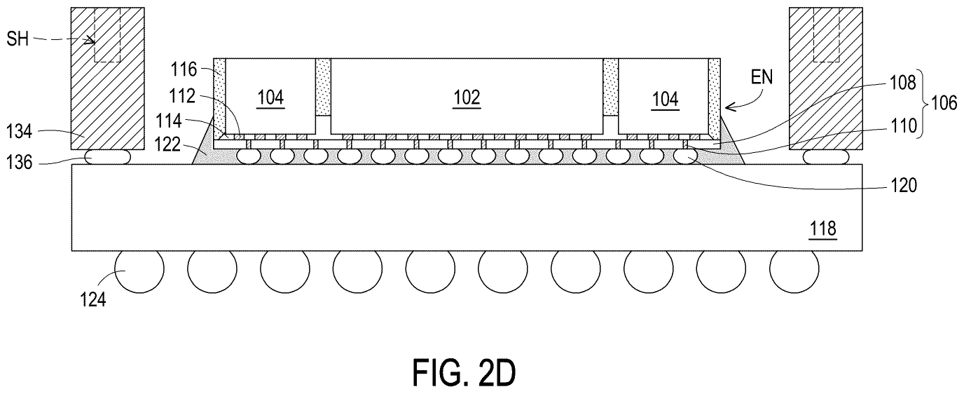

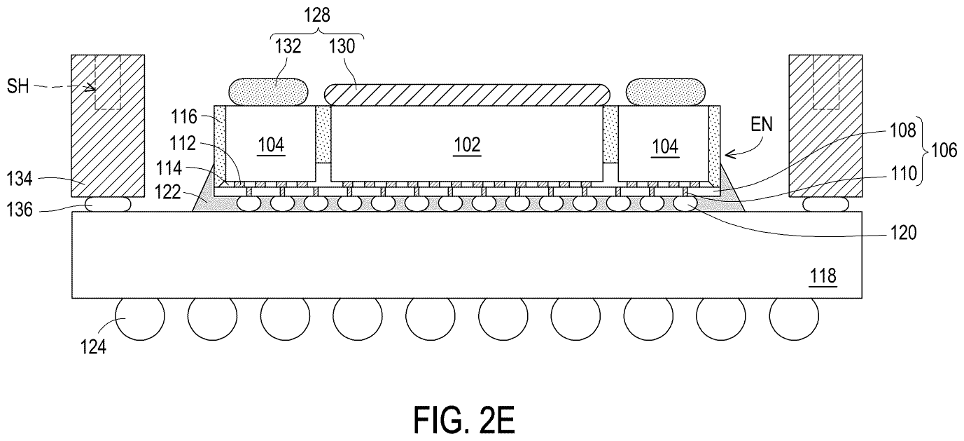

FIG. 2A through FIG. 2E are schematic cross-sectional views illustrating intermediate structures at various stages during a manufacturing process for forming the semiconductor package module 100 as described with reference to FIG. 1C, according to some embodiments of the present disclosure.

Referring to FIG. 2A, the device die 102 and the die stacks 104 are attached to an interposer substrate 200. The interposer substrate 200 will be singulated to form an interposer. In those embodiments where the interposer substrate 200 is going to be singulated to form the interposer 106 as described with reference to FIG. 1, the interposer substrate 200 may include a semiconductor substrate 202 and the TSVs 110 formed in the semiconductor substrate 202. The front sides of the device die 102 and bottommost dies of the die stacks 104 may face toward the interposer substrate 200. In some embodiments, the device die 102 and the die stacks 104 are attached to the interposer substrate 200 via the electrical connectors 112. Further, in some embodiments, an underfill 204 is provided in the space between the interposer substrate 200 and the device die 102 as well as the die stacks 104, and will be singulated to form the underfill 114 as described with reference to FIG. 1C.

Referring to FIG. 2B, the device die 102 and the die stacks 104 attached on the interposer substrate 200 are laterally encapsulated by an encapsulant 206. The encapsulant 206 may be provided on the underfill 204, and laterally surround the device die 102 and the die stacks 104. In a subsequent singulation step, the encapsulant 206 may be singulated to form the encapsulant 116 as described with reference to FIG. 1C. Moreover, the electrical connectors 120 may be formed at a side of the interposer substrate 200 facing away from the device die 102 and the die stacks 104.

Referring to FIG. 2C, the package structure as shown in FIG. 2B is singulated, and an obtained package structure is then attached to the package substrate 118 via the electrical connectors 120. During the singulation process, the encapsulant 206 is singulated to form the encapsulant 116. Further, in some embodiments, the interposer substrate 200 is singulated to form the interposer 106. In addition, in those embodiments where the underfill 204 is previously provided between the interposer substrate 200 and the device die 102 as well as the die stacks 104, the underfill 204 may be singulated to form the underfill 114. After the attachment, the underfill 122 may be further provided on the package substrate 118, to laterally surround the electrical connectors 120. In some embodiments, the underfill 122 may further extend to sidewalls of the interposer 106 and the encapsulated structure EN including the device die 102 and the die stacks 104 laterally encapsulated by the encapsulant 116. Moreover, in addition to the package structure, other electronic components (not shown, such as passive devices) may optionally be attached onto the package substrate 118.

Up to here, a semiconductor package 208 has been formed on the package substrate 118. Subsequently, components will be formed on the semiconductor package 208 and the package substrate 118 for facilitating heat dissipation of the semiconductor package 208.

Referring to FIG. 2D, in some embodiments, the ring structure 134 is attached onto the package substrate 118 via the adhesive 136. In those embodiments where the subsequently disposed heat spreader 126 is fastened to the ring structure 134 by screws (e.g., the screws 138 as described with reference to FIG. 1C), the ring structure 134 may be provided with screw holes SH extending into the ring structure 134 from a top surface of the ring structure 134. In addition, in some embodiments, the current structure is subjected to a thermal treatment for curing the adhesive 136. Moreover, in some embodiments, the electrical connectors 124 are formed at a side of the package substrate 118 facing away from the interposer 106 and the encapsulated structure EN. The electrical connectors 124 may be formed before or after formation of the ring structure 134 and the adhesive 136.

Referring to FIG. 2E, in some embodiments, the composite thermal interfacial layer 128 including the metallic layer 130 and the gel TIM 132 is provided on the encapsulated structure EN. As described above, according to some embodiments, the metallic layer 130 may be provided on the encapsulated structure EN as a metal foil. In these embodiments, the metallic layer 130 as a metal foil may be placed on the encapsulated structure EN. Alternatively, the metallic layer 130 may be provided on the encapsulated structure EN as a fluid. In these alternative embodiments, the metallic layer 130 in liquid state may be provided on the encapsulated structure EN via a dispense process or a printing process. On the other hand, the gel TIM 132 may be provided by a dispense process or a printing process. In those embodiments where the metallic layer 130 is provided as fluid, the gel TIM 132 may be provided before formation of the metallic layer 130. In alternative embodiments where the metallic layer 130 is provided as a metal foil, the gel TIM 132 may be provided before or after formation of the metallic layer 130.

Referring to FIG. 1C, in some embodiments, the heat spreader 126 is then attached to the encapsulated structure EN through the composite thermal interfacial layer 128, and fastened to the ring structure 134. The engaging portion 126b of the heat spreader 126 may be in contact with the device die 102, the die stacks 104 and the encapsulant 116 through the composite thermal interfacial layer 128. In addition, the plate portion 126a of the heat spreader 126 may be fastened to the ring structure 134 by, for example, the screws 138. Further, in some embodiments, the heat spreader 126 may be provided with the wicking structure 140 coated on surface(s) of the heat spreader 126. In those embodiments where the wicking structure 140 includes a microporous sintered metal powder coating layer, a material including metallic powders (with or without functional coating(s)) and an organic binder may be provided on the surface(s) of the heat spreader 126 by, for example, a printing process, then the printed heat spreader 126 may be transferred to a furnace for performing a sintering process. Sintered coating may form the wicking structure 140.

Up to here, the semiconductor package module 100 as described with reference to FIG. 1C has been formed. In some embodiments, a plurality of the semiconductor package modules 100 may be attached to the printed circuit boards MB (as shown in FIG. 1A) through the electrical connectors 124. Further, additional components may be further mounted onto the printed circuit board MB, and the electronic system 10 according to some embodiments can be formed.

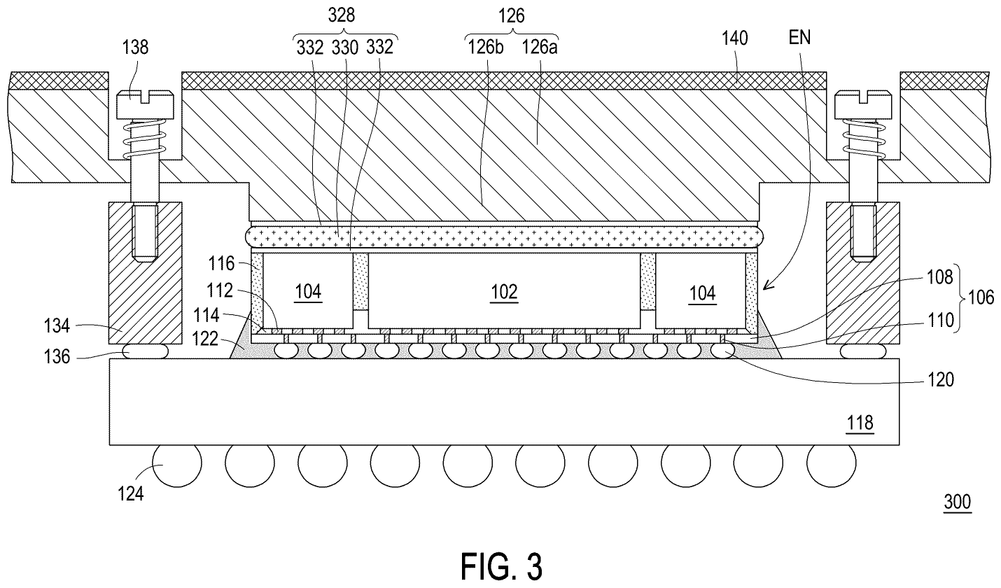

FIG. 3 is a schematic cross-sectional view illustrating a semiconductor package module 300, according to some embodiments of the present disclosure. The semiconductor package module 300 is similar to the semiconductor package module 100 as described with reference to FIG. 1C. Only differences between the semiconductor package modules 100, 300 will be described, the same or the like parts of the semiconductor package modules 100, 300 would not be repeated again.

Referring to FIG. 3, in some embodiments, the heat spreader 126 is attached to the encapsulated structure EN through a composite thermal interfacial layer 328. The composite thermal interfacial layer 328 may include a metallic TIM 330 and adhesion layers 332 covering opposite sides of the metallic TIM 330. In some embodiments, the metallic TIM 330 is provided as a metallic foil, and may be attached with each of the adhesion layers 332 through a solder layer (not shown). In these embodiments, the metallic TIM 330 may be formed of indium, indium alloy (e.g., indium-tin alloy), copper, copper alloy, bismuth alloy, gallium, rhodium, the like or combinations thereof, and have a melting temperature ranging from 60° C. to 120° C. . . . In alternative embodiments, the metallic TIM 330 is provided as a paste, and may be in direct contact with the adhesion layers 332. In these alternative embodiments, the metallic TIM 330 may include metallic powders formed of, for example, silver or silver alloy, and further include flux for binding these metallic powders. On the other hand, in some embodiments, the adhesion layers 332 are respectively formed of a metal alloy including Ti, Cu, Ni, V, Au, the like or combinations thereof.

In some embodiments, the metallic TIM 330 and the adhesion layers 332 globally cover the encapsulated structure EN. In these embodiments, one of the adhesion layers 332 extends along back surface of the encapsulated structure EN facing away from the interposer 106, and the other adhesion layer 332 extends along a bonding surface of the engaging portion 126b of the heat spreader 126. Further, the metallic TIM 330 is sandwiched between the adhesion layers 332.

As compared to a grease TIM layer or a gel TIM layer, the composite thermal interfacial layer 328 has a reduced thermal resistance, thus heat generated from the encapsulated structure EN can be more effectively transferred to the heat spreader 126 through the composite thermal interfacial layer 328.

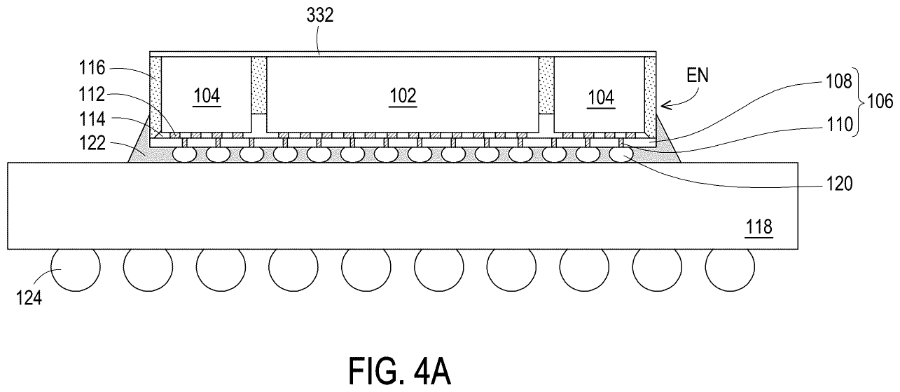

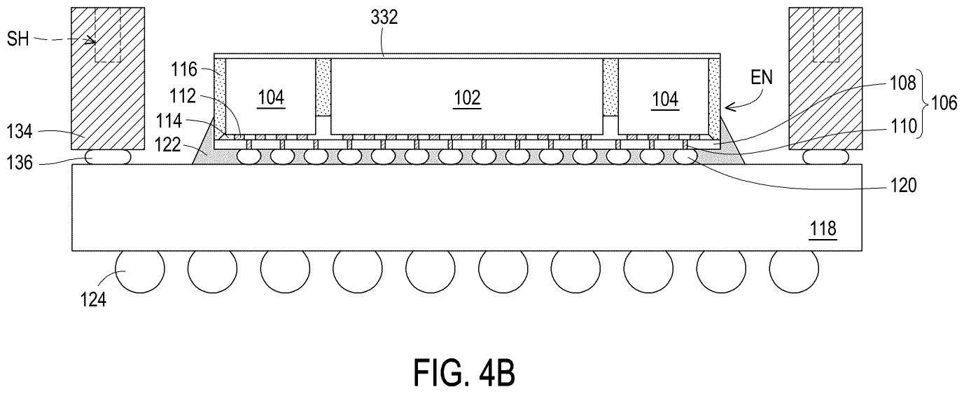

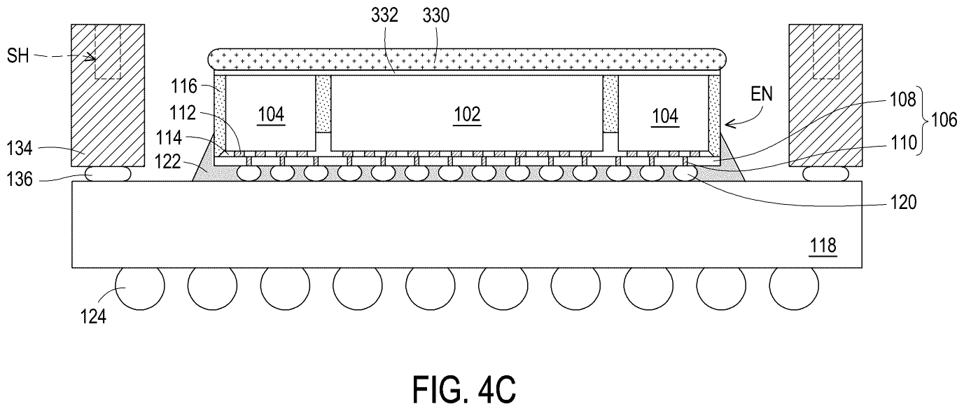

FIG. 4A through FIG. 4C are schematic cross-sectional views illustrating intermediate structures at various stages during a manufacturing process for forming the semiconductor package module 300 as described with reference to FIG. 3, according to some embodiments of the present disclosure.

Referring to FIG. 4A, according to some embodiments, one of the adhesion layers 332 is formed on the semiconductor package 208 provided in the steps described with reference to FIG. 2A through FIG. 2C. The adhesion layer 332 may be deposited on a back surface of the encapsulated structure EN facing away from the package substrate 118. As an example, a sputtering process may be used for depositing the adhesion layer 332 on the encapsulated structure EN.

Referring to FIG. 4B, the adhesive 136 and the ring structure 134 are provided on the package substrate 118, as described with reference to FIG. 2D. In those embodiments where the one of the adhesion layers 332 is formed before placing the adhesive 136 and the ring structure 134, the adhesive 136 and the ring structure 134 are disposed with the encapsulated structure EN covered by the adhesion layer 332.

Referring to FIG. 4C, the metallic TIM 330 is provided on the previously formed adhesion layer 332. In those embodiments where the metallic TIM 330 is in a form of a metal foil, the metallic TIM 330 may be provided on the adhesion layer 332 via, for example, a lamination process. In addition, in these embodiments, a solder paste (not shown) may be preliminarily provided on the adhesion layer 332. After the foil-type metallic TIM 330 is provided on the solder paste, the solder paste may be heated to form a solder layer for establishing bonding between the foil-type metallic TIM 330 and the adhesion layer 332. In alternative embodiments where the metallic TIM 330 is provided as a paste, the metallic TIM 330 may be formed on the adhesion layer 332 via a dispense process or a printing process.

Referring to FIG. 3, the heat spreader 126 (which may be preliminarily coated with the wicking structure 140) is then attached to the metallic TIM 330 and fastened to the ring structure 134. In some embodiments, another adhesion layer 332 is formed on a bonding surface of the engaging portion 126b of the heat spreader 126 before the heat spreader 126 is attached onto the metallic TIM 330. By attaching the heat spreader 126 coated with the adhesion layer 332 onto the metallic TIM 330, the composite thermal interfacial layer 328 is formed along with the attachment. The adhesion layer 332 may be formed by a deposition process. As an example, a sputtering process may be used for depositing the adhesion layer 332 on the bonding surface of the heat spreader 126. In those embodiments where the metallic TIM 330 is provided as a metal foil, a solder paste (not shown) may be provided on the adhesion layer 332 coated on the heat spreader 126. After the heat spreader 126 coated with the adhesion layer 332 is attached to the metallic TIM 330, the solder paste may be heated to form a solder layer for establishing bonding between the adhesion layer 332 and the metallic TIM 330.

Up to here, the semiconductor package module 300 as described with reference to FIG. 3 has been formed. Moreover, a plurality of the semiconductor package modules 300 may be subjected to further processes, to form an electronic system similar to the electronic system 10 as shown in FIG. 1A.

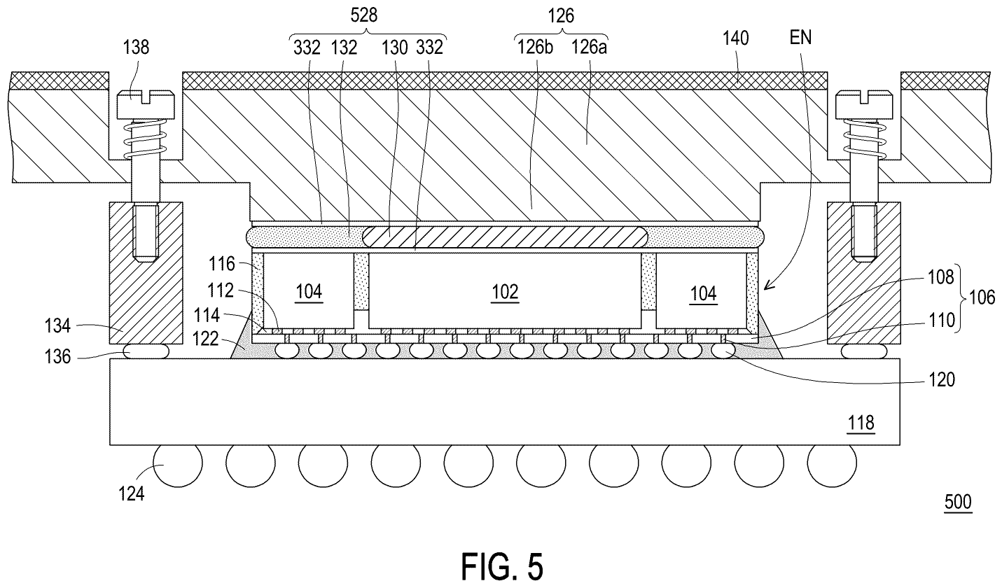

FIG. 5 is a schematic cross-sectional view illustrating a semiconductor package module 500, according to some embodiments of the present disclosure. The semiconductor package module 500 may be described as being derived from the semiconductor package modules 100, 300 as described with reference to FIG. 1C and FIG. 3. Only differences between the semiconductor package module 500 and the semiconductor package modules 100, 300 will be described, the same or the like parts of the semiconductor package modules 100, 300, 500 would not be repeated again.

Referring to FIG. 5, in some embodiments, the heat spreader 126 is attached to the encapsulated structure EN through a composite thermal interfacial layer 528. The composite thermal interfacial layer 528 may include the metallic layer 130 and the gel TIM 132 laterally enclosing the metallic layer 130, as described with reference to FIG. 1C. Further, the composite thermal interfacial layer 528 may further include the adhesion layers 332, as described with reference to FIG. 3. In these embodiments, the metallic layer 130 and the get TIM 132 are sandwiched between the adhesion layers 332.

A manufacturing process for forming the semiconductor package module 500 is similar to the manufacturing process for forming the semiconductor package module 300 (as described with reference to FIG. 4A through FIG. 4C and FIG. 3), except that the metallic layer 130 and the gel TIM 132 (instead of the metallic TIM 330) are formed on the lower adhesion layer 332, and the engaging portion 126b of the heat spreader 126 coated with the upper adhesion layer 332 is attached to the metallic layer 130 and the gel TIM 132 (rather than the metallic TIM 330).

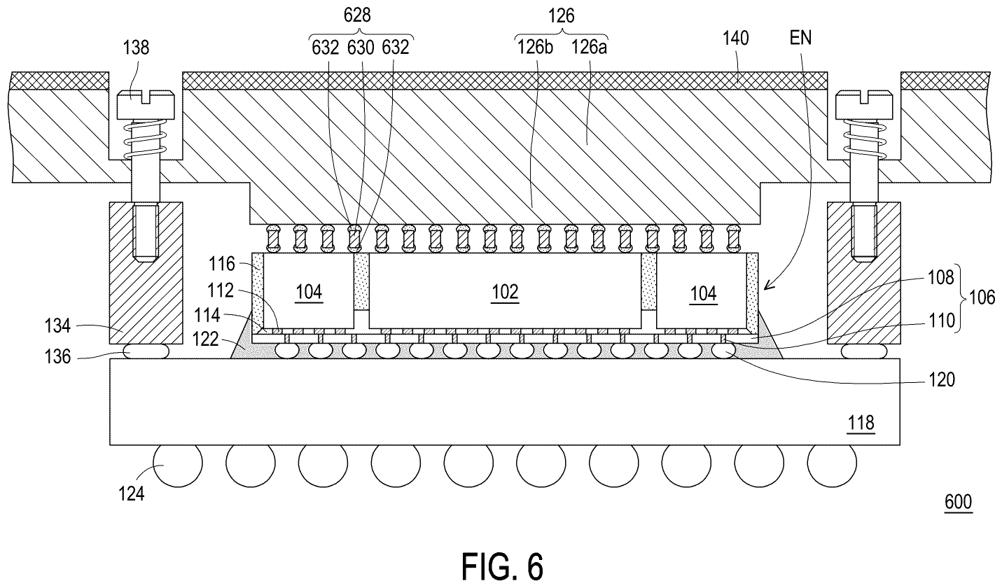

FIG. 6 is a schematic cross-sectional view illustrating a semiconductor package module 600, according to some embodiments of the present disclosure. The semiconductor package module 600 is different from the semiconductor package modules 100, 300, 500 (as described with reference to FIG. 1C, FIG. 3 and FIG. 5) in terms of how the heat spreader 126 is attached to the encapsulated structure EN. Only differences between the semiconductor package module 600 and the semiconductor package modules 100, 300, 500 will be described, the same or the like parts of the semiconductor package modules 100, 300, 500, 600 would not be repeated again.

Referring to FIG. 6, in some embodiments, the heat spreader 126 is attached to the encapsulated structure EN through pillar structures 628. The pillar structures 628 may respectively include a conductive pillar 630 extending vertically between the engaging portion 126b of the heat spreader 126 and the encapsulated structure EN, and may include solder joints 632 attaching terminals of the conductive pillar 630 to the engaging portion 126b of the heat spreader 126 and the encapsulated structure EN, respectively. As an example, the conductive pillars 630 may be copper pillars. In some embodiments, the pillar structures 628 are separately distributed across the back surface of the encapsulated structure EN facing away from the package substrate 118.

As compared to a grease TIM layer or a gel TIM layer, the conductive pillars 630 in the pillar structures 628 have a lower thermal resistance, thus heat generated from the encapsulated structure EN can be more effectively transferred to the heat spreader 126 through the pillar structures 628.

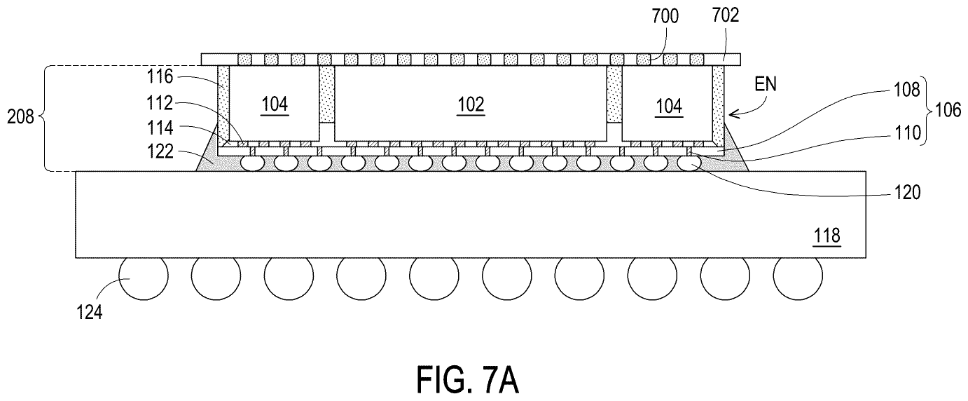

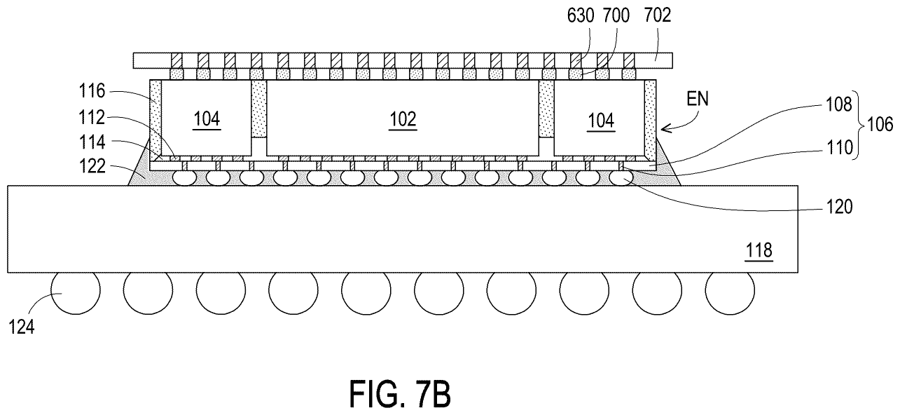

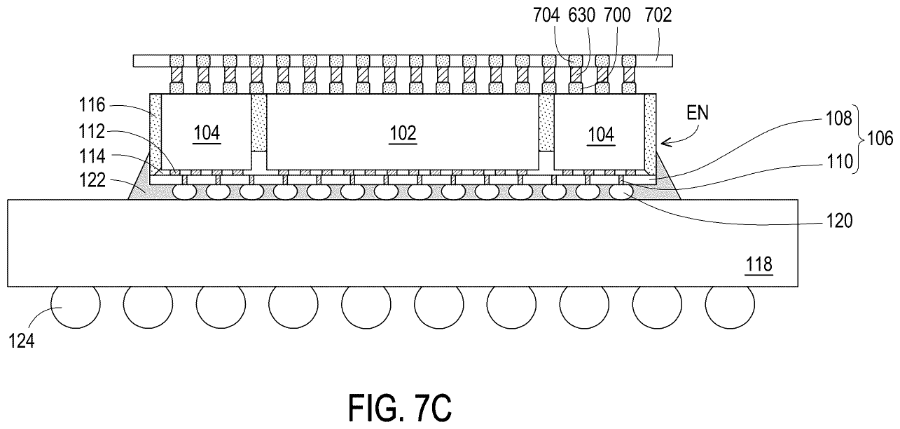

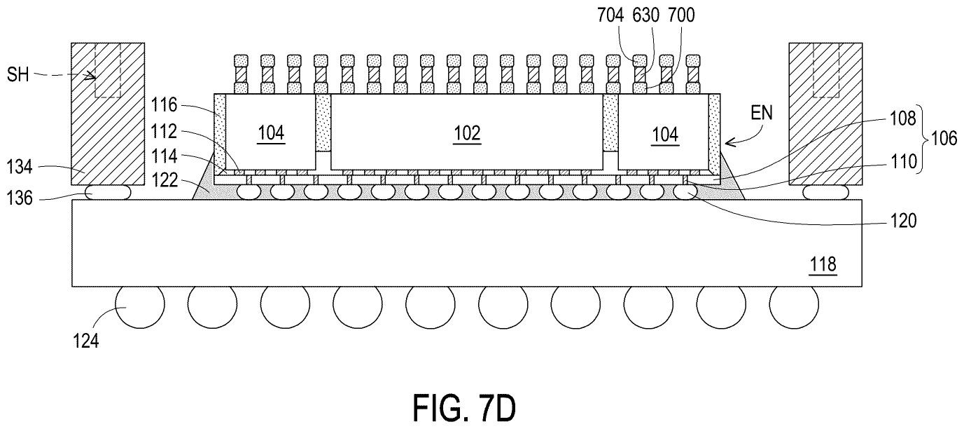

FIG. 7A through FIG. 7D are schematic cross-sectional views illustrating intermediate structures at various stages during a manufacturing process for forming the semiconductor package module 600 as described with reference to FIG. 6, according to some embodiments of the present disclosure.

Referring to FIG. 7A, solder pastes 700 are formed on the semiconductor package 208 provided in the steps described with reference to FIG. 2A through FIG. 2C, and will be reshaped to form the lower solder joints 632 as described with reference to FIG. 6. In some embodiments, the solder pastes 700 are provided via a stencil printing process. In these embodiments, a stencil 702 with multiple openings is placed on the encapsulated structure EN of the semiconductor package 208. Subsequently, a solder paste material is provided on the stencil 702, and a squeegee (not shown) may be used to force the solder paste material rolling into the openings of the stencil 702. The solder paste material left in these openings form the solder pastes 700.

Referring to FIG. 7B, in some embodiments, the stencil 702 is elevated over the solder pastes 700. Currently, the openings of the stencil 702 overlap the underlying solder pastes 700, respectively. A plurality of conductive pillars are provided on the stencil 702, and those conductive pillars dropping into the openings of the stencil 702 and standing on the solder pastes 700 form the conductive pillars 630.

Referring to FIG. 7C, in some embodiments, the stencil 702 is further elevated over the conductive pillars 630. Currently, the openings of the stencil 702 overlap the underlying conductive pillars 630. A solder paste material is provided on the stencil 702, and a squeegee (not shown) may be used to force the solder paste material rolling into the openings of the stencil 702. The solder paste material left in these openings form solder pastes 704. The solder pastes 704 will be reshaped to form the upper solder joints 632 as described with reference to FIG. 6. After forming the solder pastes 704, the stencil 702 may be removed.

Referring to FIG. 7D, the adhesive 136 and the ring structure 134 are provided on the package substrate 118, as described with reference to FIG. 2D. In alternative embodiments, the adhesive 136 and the ring structure 134 are provided before formation of the conductive pillars 630 and the solder pastes 700, 704.

Referring to FIG. 6, the heat spreader 126 (which may be preliminarily coated with the wicking structure 140) is placed on the current structure, and the entire structure may be subjected to a heat treatment. During the heat treatment, the solder pastes 700, 704 may reflow in a molten state, and may be reshaped to form the solder joints 632 as described with reference to FIG. 6. As a result, the pillar structures 628 including the conductive pillars 632 and the solder joints 632 are formed, and the engaging portion 126b of the heat spreader 126 is attached to the encapsulated structure EN through the pillar structures 628. In addition, the heat spreader 126 may be fastened to the ring structure 134 by using, for example, the screws 138. In some embodiments, the fastening operation precedes the heat treatment. In alternative embodiments, the heat treatment is followed by the fastening operation.

Up to here, the semiconductor package module 600 as described with reference to FIG. 6 has been formed. Moreover, a plurality of the semiconductor package modules 600 may be subjected to further processes, to form an electronic system similar to the electronic system 10 as shown in FIG. 1A.

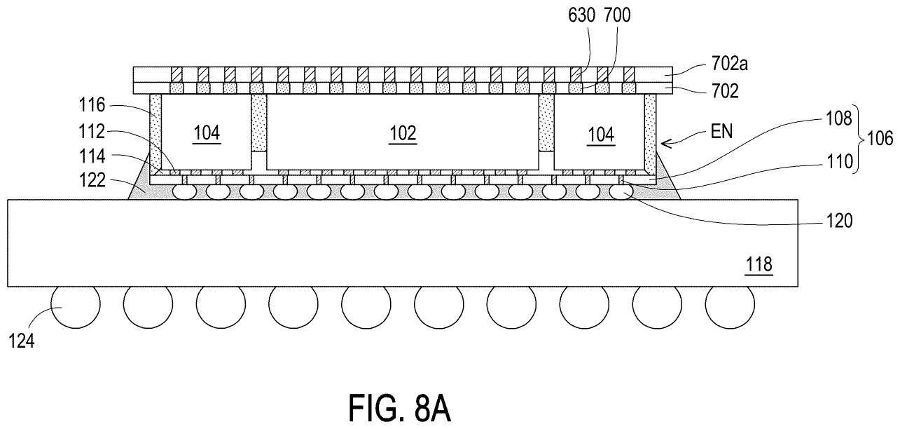

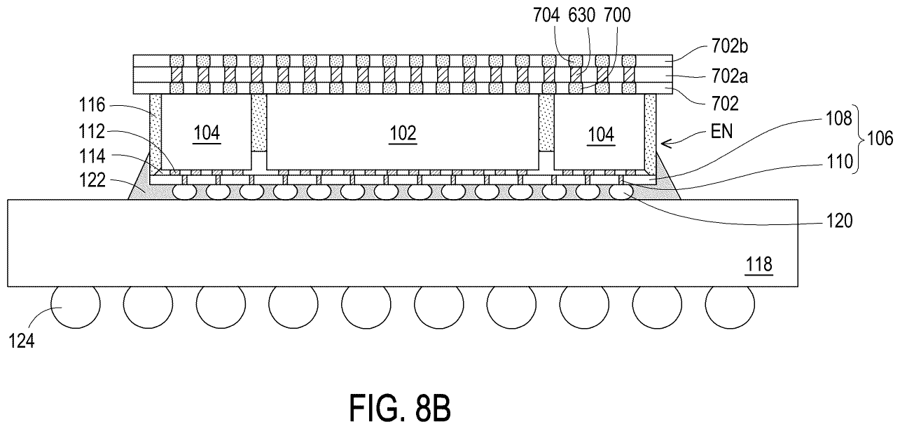

FIG. 8A and FIG. 8B are schematic cross-sectional views illustrating intermediate structures at various stages during a manufacturing process for forming pillar structures 628 as described with reference to FIG. 6, according to some embodiments of the present disclosure.

Referring to FIG. 8A, according to some embodiments, after forming the solder pastes 700 by using the stencil 702, another stencil 702a may be stacked on the stencil 702 for positioning the conductive pillars 630. In these embodiments, the stencil 702 may not be removed immediately after formation of the solder pastes 700.

Referring to FIG. 8B, an additional stencil 702b may be further stacked on the stencil 702a with openings accommodating the conductive pillars 630, and a stencil printing process using the stencil 702b may be performed for forming the solder pastes 704. Once the solder pastes 704 are formed, the stencils 702, 702a, 702b may be removed. Subsequently, as described with reference to FIG. 7D and FIG. 6, the adhesive 136 and the ring structure 134 may be disposed on the package substrate 118. In addition, after the heat spreader 126 is in contact with the solder pastes 704, a heat treatment may be performed to reshape the solder pastes 700, 704, for forming the solder joints 632. Further, the heat spreader 126 may be fastened to the ring structure 134.

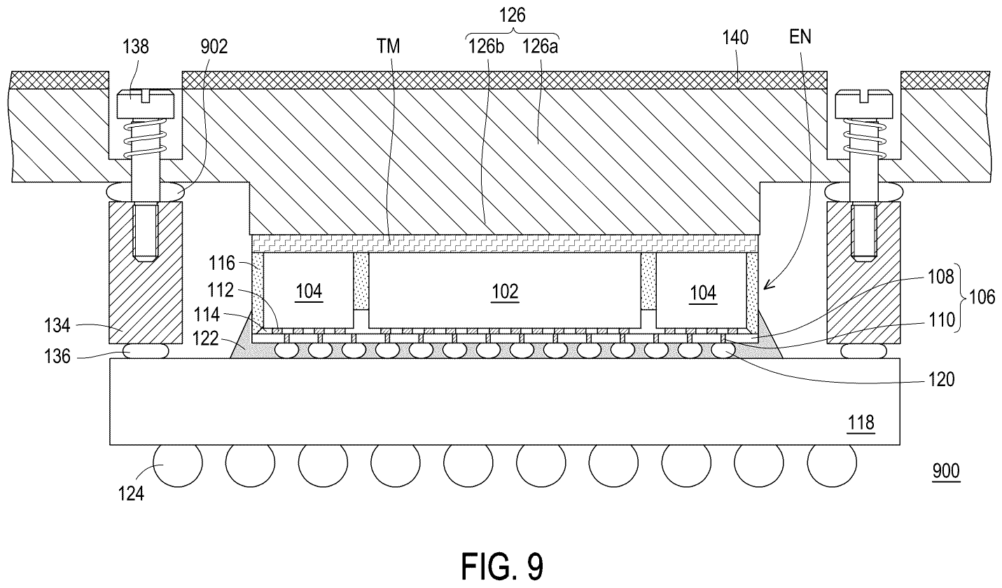

FIG. 9 is a schematic cross-sectional view illustrating a semiconductor package module 900, according to some embodiments of the present disclosure. A mechanism to reduce impact resulted from placement of the heat spreader will be described, and such mechanism is applicable to other embodiments described in the present disclosure.

Referring to FIG. 9, an attach stopper 902 is further provided between the ring structure 134 and the plate portion 126a of the heat spreader 126. The attach stopper 902 may absorb impact and reduce pressure applied on the ring structure 134 and the package substrate 118 when the heat spreader 126 is placed on and fastening to the ring structure 134, thus may protect the ring structure 134 and the package substrate 118 from possible damages. The attach stopper 902 may be formed of an elastic material, such as rubber or elastomer. In some embodiments, the attach stopper 902 spans along a top surface of the ring structure 134. In other words, the attach stopper 902 may be formed in a ring shape. Further, in those embodiments where the heat spreader 126 is fastened to the ring structure 134 by screws 138, the screws 138 may penetrate through the attach stopper 902. In regarding fabrication of the semiconductor package module 900, the attach stopper 902 may be provided after the ring structure 134 is disposed and before the heat spreader 126 is fastened to the ring structure 134.

A thermal interfacial structure TM lying between the engaging portion 126b of the heat spreader 126 and the encapsulated structure EN can be any one of the composite thermal interfacial layer 128 as shown in FIG. 1C, the composite thermal interfacial layer 328 as shown in FIG. 3 and the composite thermal interfacial layer 528 as shown in FIG. 5, or represents the pillar structures 628 as shown in FIG. 6. For conciseness, other parts of the semiconductor package module 900 similar or identical to those in the semiconductor package modules 100, 300, 500, 600 (as described with reference to FIG. 1C, FIG. 3, FIG. 5 and FIG. 6) would not be described again.

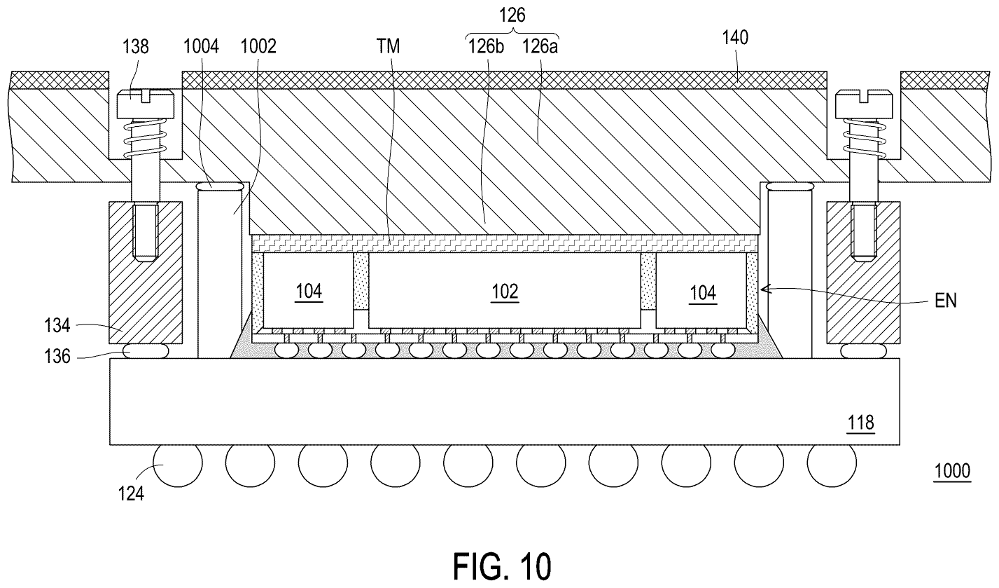

FIG. 10 is a schematic cross-sectional view illustrating a semiconductor package module 1000, according to some embodiments of the present disclosure. Another mechanism to reduce impact resulted from placement of the heat spreader will be described, and such variation is applicable to other embodiments described in the present disclosure.

Referring to FIG. 10, a seal dam 1002 is disposed on the package substrate 118, to further support the plate portion 126a of the heat spreader 126. The encapsulated structure EN along with the interposer 106 and the electrical connectors 120 are laterally enclosed by the seal dam 1002. In addition to be higher than a top surface of the thermal interfacial structure TM, a top surface of the seal dam 1002 may be higher than a top surface of the ring structure 134 as well. As a result, during placement of the heat spreader 126, the heat spreader 126 may be in contact with the seal dam 1002, while maintaining a spacing from the ring structure 134. In this way, the plate portion 126a of the heat spreader 126 can be fastened to the ring structure 134 with support provided by the seal dam 1002. In some embodiments, the seal dam 1002 is formed of a polymer material, such as polydimethylsiloxane (PDMS). Further, in some embodiments, the seal dam 1002 is in contact with the plate portion 126a of the heat spreader 126 through an attach stopper 1004. The attach stopper 1004 may absorb impact and reduce pressure applied on the seal dam 1002, the ring structure 134 and the package substrate 118 during placement of the heat spreader 126, thus may protect the seal dam 1002, the ring structure 134 and the package substrate 118 from possible damages. The attach stopper 1004 may be formed of an elastic material, such as rubber or elastomer.

In regarding fabrication of the semiconductor package module 1000, the seal dam 1002 (and the attach stopper 1004) may be formed on the package substrate 118 after the interposer 106 along with components disposed thereon is attached to the package substrate 118, and before placement of the heat spreader 126.

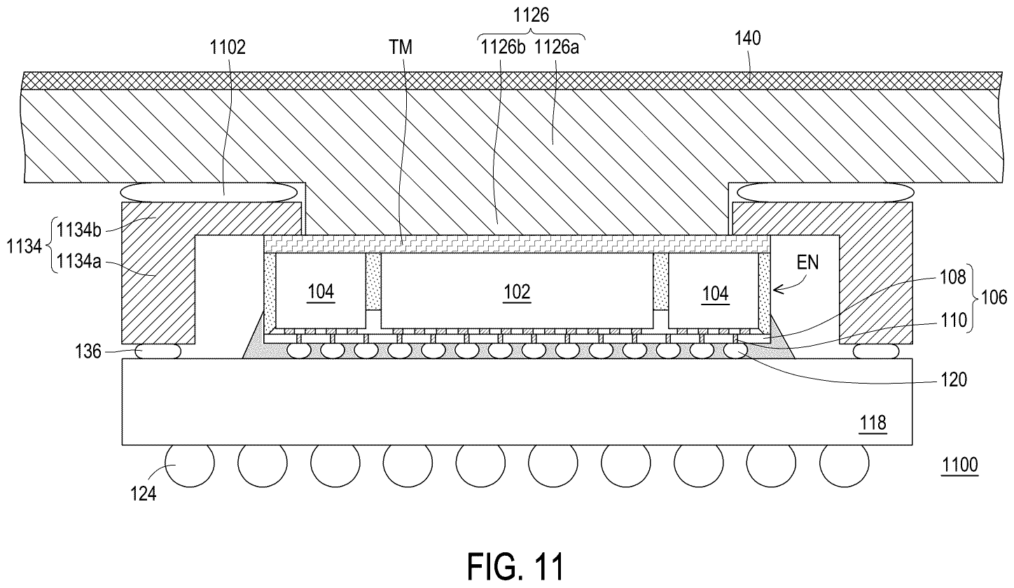

FIG. 11 is a schematic cross-sectional view illustrating a semiconductor package module 1100, according to some embodiments of the present disclosure. Variations to the ring structure and the heat spreader will be described, and such variations are applicable to other embodiments described in the present disclosure.

Referring to FIG. 11, a heat spreader 1126 has a plate portion 1126a and an engaging portion 1126b extending downwardly to the thermal interfacial structure TM from the plate portion 1126a, as similar to the heat spreader 126 described above. The engaging portion 1126b of the heat spreader 1126 may be smaller in size as compared to the thermal interfacial structure TM and the encapsulated structure EN, and a peripheral region of the thermal interfacial structure TM as well as a peripheral region of the encapsulated structure EN may not be overlapped with the engaging portion 1126b of the heat spreader 1126. Further, a ring structure 1134 attached to the package substrate 118 may have a wall portion 1134a and a laterally extending portion 1134b. The wall portion 1134a stands on the package substrate 118, and laterally encloses the encapsulated structure EN as well as the interposer 106, the electrical connectors 120, the underfill 122 and the thermal interfacial structure TM by a non-zero spacing. On the other hand, the laterally extending portion 1134b laterally extends from a top end of the wall portion 1134a to a top surface of the peripheral portion of the thermal interfacial structure TM, and bridges the wall portion 1134a of the ring structure 1134 to the thermal interfacial structure TM. Accordingly, the thermal interfacial structure TM is covered by the engaging portion 1126b of the heat spreader 1126 and the laterally extending portion 1134b of the ring structure 1134. Further, the ring structure 1134 can be attached with the plate portion 1126a of the heat spreader 1126 by the laterally extending portion 1134b. Therefore, contact area between the ring structure 1134 and the heat spreader 1126 can be increased, and the pressure applied on a peripheral region of the package substrate 118 by the heat spreader 1126 can be reduced. In some embodiments, the laterally extending portion 1134b of the ring structure 1134 is attached to the plate portion 1126a through an adhesive 1102. As an example, the adhesive 1102 may be a phase change adhesive, which may include thermally conductive adhesive, silicone based adhesive or epoxy resin based adhesive or include rubber based content with curing promoting material. As an example, the adhesive 1102 may be a phase change adhesive formed of silicone-based elastomer and should be operational in a temperature range of −45° C. to 200° C.

In regarding fabrication of the semiconductor package module 1100, the ring structure 1134 is provided on the package substrate 118 after the interposer 106 along with components disposed thereon are attached to the package substrate 118, and before placement of the heat spreader 1126.

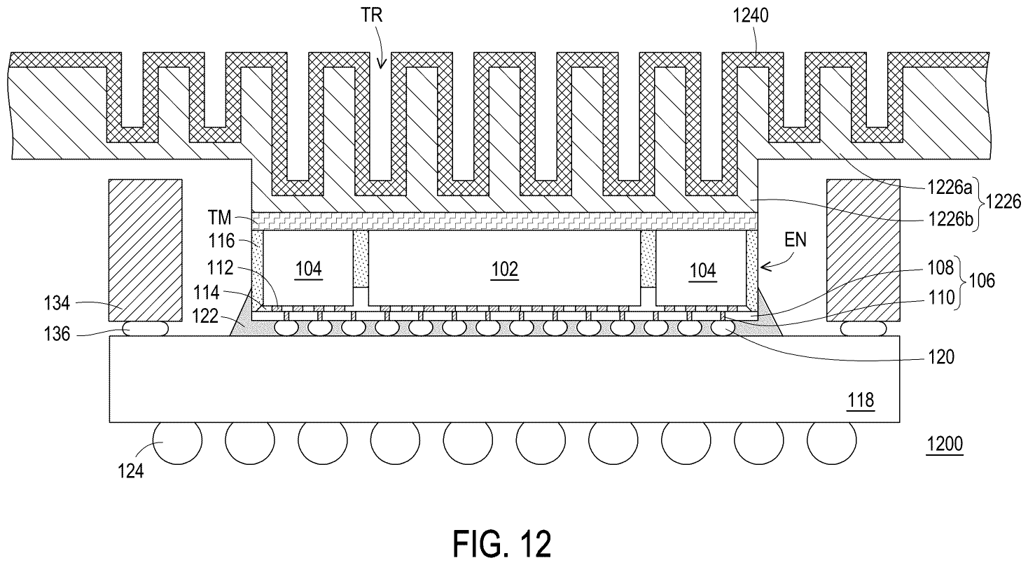

FIG. 12 is a schematic cross-sectional view illustrating a semiconductor package module 1200, according to some embodiments of the present disclosure. A variation to the heat spreader will be described, and such variation is applicable to other embodiments described in the present disclosure.

Referring to FIG. 12, a heat spreader 1226 in contact with the thermal interfacial structure TM and the ring structure 134 is formed with trenches TR, in order to increase heat exchange area. The trenches TR extend into the heat spreader 1226 from a side of the heat spreader 1226 facing away from the thermal interfacial structure TM and the ring structure 134, but may not penetrate through the heat spreader 1226. As similar to the heat spreader described above, the heat spreader 1226 has a laterally spanning plate portion 1226a and an engaging portion 1226b extending downwardly from the plate portion 1226b. The trenches TR are formed in the plate portion 1226a. In some embodiments, the trenches TR within a region, where the plate portion 1226a and the engaging portion 1226b are overlapped, further extend into the engaging portion 1226b, and have a depth greater than a depth of other trenches TR only extending in the plate portion 1226a. Further, in some embodiments where the semiconductor package module 1200 is designed to be compatible with a two-phase immersion cooling apparatus (e.g., the immersion cooling apparatus 160 as shown in FIG. 1B), the heat spreader 1226 may be conformally coated with one or more layer of wicking structure 1240. The wicking structure 1240 may include a porous layer or include microstructures (e.g., mesh, bumps etc.), as similar to the wicking structure 140 described with reference to FIG. 1C. In some embodiments, the side of the heat spreader 1226 formed with the trenches TR is coated with the wicking structure 1240. In other embodiments, all of the surfaces of the heat spreader 1226 in contact with the dielectric cooling liquid 164 (as shown in FIG. 1B) are coated with the wicking structure 1240.

It should be noted that, although not shown, the heat spreader 1226 may be fastened to the ring structure 134 by screws, as similar to the embodiments described with reference to FIG. 1C, FIG. 3, FIG. 5, FIG. 6, FIG. 9 and FIG. 10. Alternatively, the heat spreader 1226 may be attached to the ring structure 134 by an adhesive (not shown). Further, an attach stopper may be formed between the ring structure 134 and the heat spreader 1226, as similar to the embodiments described with reference to FIG. 9.

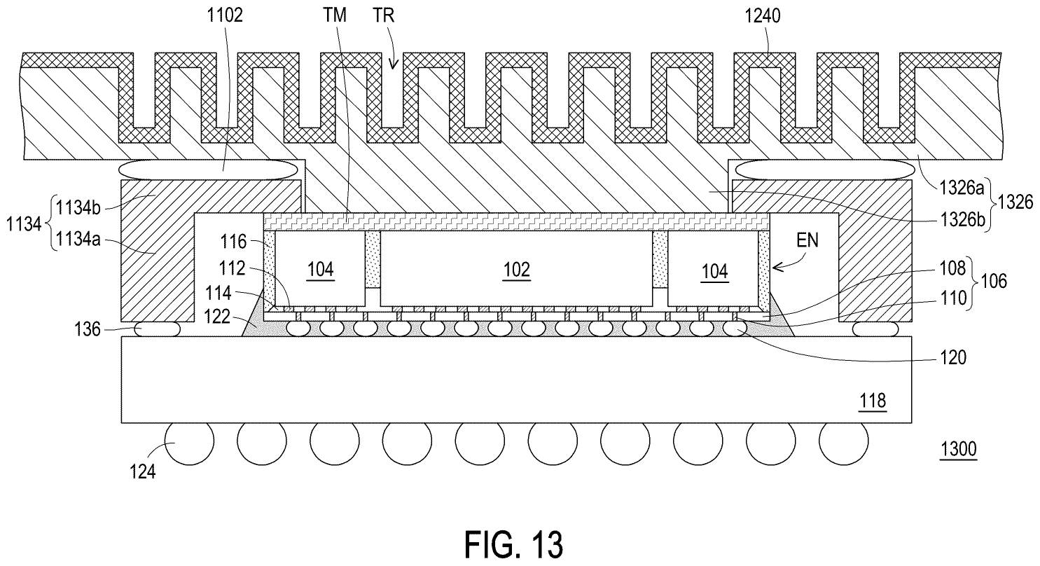

FIG. 13 is a schematic cross-sectional view illustrating a semiconductor package module 1200, according to some embodiments of the present disclosure. As will be described, variations to the ring structure and the heat spreader described with reference to FIG. 11 are applied on the embodiments described with reference to FIG. 12.

Referring to FIG. 13, a heat spreader 1326 having a plate portion 1326a and an engaging portion 1326b is formed with trenches TR, as similar to the heat spreader 1226 described with reference to FIG. 12. In some embodiments, the trenches TR are all confined in the plate portion 1326a, and may not further extend to the engaging portion 1326b, even for some of the trenches TR within a region of the heat spreader 1326 where the plate portion 1326a is overlapped with the engaging portion 1326b. In these embodiments, all of the trenches TR may have substantially identical depth. In alternative embodiments, the trenches TR within the region of the heat spreader 1326 (where the plate portion 1326a and the engaging portion 1326b are overlapped) further extend to the engaging portion 1326b.

In some embodiments, the plate portion 1326a of the heat spreader 1326 is attached to the laterally extending portion 1134b of the ring structure 1134. In these embodiments, the engaging portion 1326b of the heat spreader 1326 may be laterally recessed with respect to the thermal interfacial structure TM, and the laterally extending portion 1134b of the ring structure 1134 may extend to a peripheral region of the thermal interfacial structure TM not covered by the engaging portion 1326b of the heat spreader 1326. Further, in some embodiments, the plate portion 1126a of the heat spreader 1126 is attached to the laterally extending portion 1134b of the ring structure 1134 through the adhesive 1102.

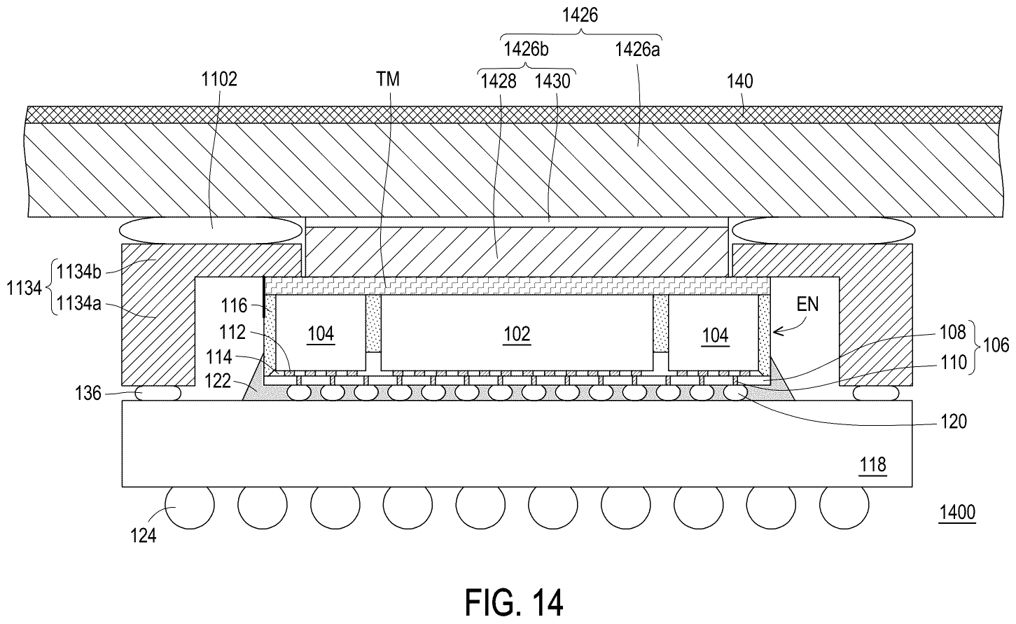

FIG. 14 is a schematic cross-sectional view illustrating a semiconductor package module 1400, according to some embodiments of the present disclosure. A variation to the heat spreader will be described, and such variation is applicable to other embodiments described in the present disclosure.

Referring to FIG. 14, as similar to the heat spreaders described above, a heat spreader 1426 has a plate portion 1426a laterally extending over the thermal interfacial structure TM, and has an engaging portion 1426b extending downwardly to the thermal interfacial structure TM from the plate portion 1426a. As different from other heat spreaders, the plate portion 1426a and the engaging portion 1426b of the heat spreader 1426 may be formed of different materials. The engaging portion 1426b may include a material with thermal conductivity greater than a thermal conductivity of a material for forming the plate portion 1426a. As an example, the engaging portion 1426b may include a high thermal conductivity lid 1428 formed of silver diamond alloy, copper diamond alloy or the like, while the plate portion 1426a may be formed of copper, aluminum, cobalt or copper coated with nickel. Moreover, the engaging portion 1426b may further include an adhesion layer 1430 attaching the high thermal conductivity lid 1428 of the engaging portion 1426b to the plate portion 1426a. In some embodiments, the adhesion layer 1430 entirely overlaps the high thermal conductivity lid 1428, and may have a sidewall substantially coplanar with a sidewall of the high thermal conductivity lid 1428. As an example, the adhesion layer 1430 may be formed of a metal alloy including, but not limited to, Ti, Au, Cu, Ni, V, Au, the like or combinations thereof.

In some embodiments, the plate portion 1426a of the heat spreader 1426 is attached to the laterally extending portion 1134b of the ring structure 1134, which is described with reference to FIG. 11. In these embodiments, the high thermal conductivity lid 1428 and the adhesion layer 1430 may be laterally recessed with respect to the thermal interfacial structure TM, such that a peripheral region of the thermal interfacial structure TM can be landed by the laterally extending portion 1134b of the ring structure 1134. Further, the adhesive 1102 may be further disposed between the laterally extending portion 1134b of the ring structure 1134 and the plate portion 1426a of the heat spreader 1426.

Alternatively, the plate portion 1426a of the heat spreader 1426 may be fastened to the ring structure 134 as similar to the embodiments described with reference to FIG. 1C, FIG. 3, FIG. 5, FIG. 6, FIG. 9, and may be further supported by the seal dam 1002 as similar to the embodiments described with reference to FIG. 10.

In regarding fabrication of the semiconductor package module 1400, the engaging portion 1426b may be preliminarily formed on the plate portion 1426 before entire heat spreader 1426 is attached to the thermal interfacial structure TM.

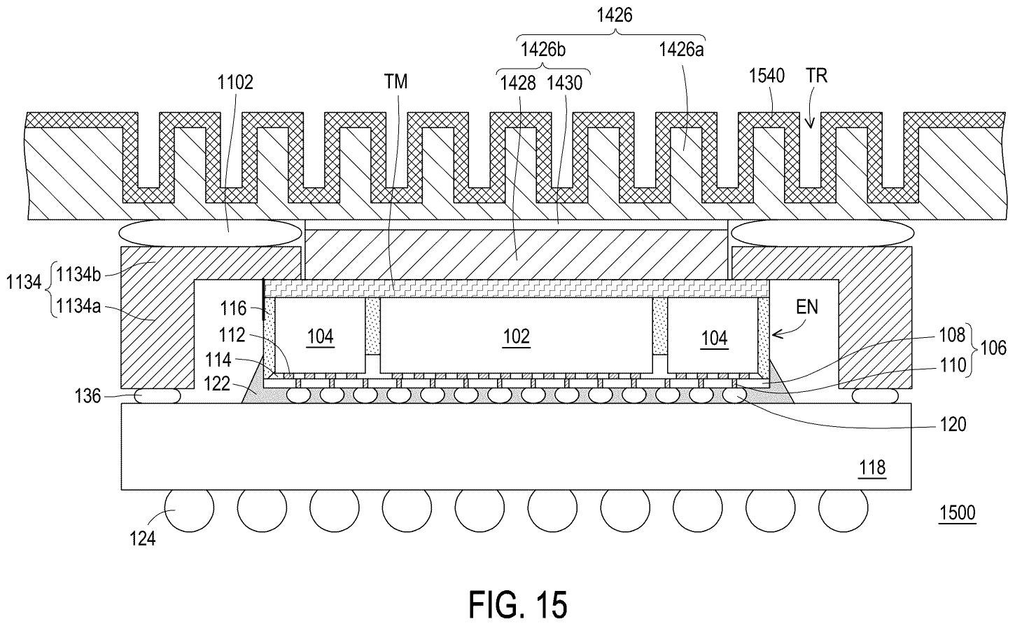

FIG. 15 is a schematic cross-sectional view illustrating a semiconductor package module 1500, according to some embodiments of the present disclosure. As will be described, a variation to the heat spreader described with reference to FIG. 13 is applied on the embodiments described with reference to FIG. 14.

Referring to FIG. 15, trenches TR are further formed in the plate portion 1426a of the heat spreader 1426. In some embodiments, the trenches TR are confined in the plate portion 1426a, and may not further extend to the engaging portion 1426b, even for some of the trenches TR within a region of the heat spreader 1426 where the plate portion 1426a and the engaging portion 1426b are overlapped. In these embodiments, all of the trenches TR may have substantially identical depth. Further, in some embodiments where the semiconductor package module 1500 is designed to be compatible with a two-phase immersion cooling apparatus (e.g., the immersion cooling apparatus 160 as shown in FIG. 1B), the heat spreader 1426 may be conformally coated with one or more layers of wicking structure 1540. The wicking structure 1540 may include a porous layer or include microstructures (e.g., mesh, bumps etc.), as similar to the wicking structure 140 described with reference to FIG. 1C. In some embodiments, the side of the heat spreader 1426 formed with the trenches TR is coated with the wicking structure 1540. In other embodiments, all of the surfaces of the heat spreader 1426 in contact with the dielectric cooling liquid 164 (as shown in FIG. 1B) are coated with the wicking structure 1540.

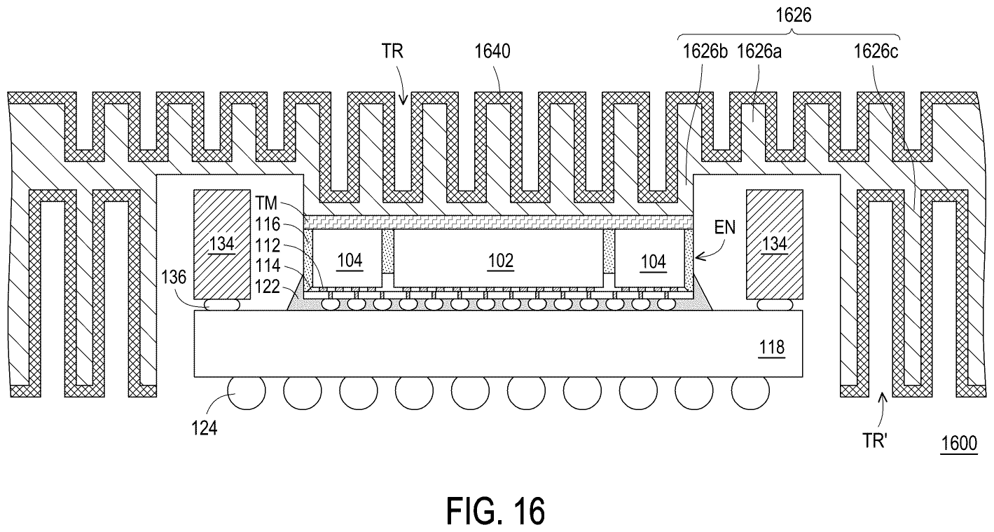

FIG. 16 is a schematic cross-sectional view illustrating a semiconductor package module 1600, according to some embodiments of the present disclosure. As will be described, a variation to the heat spreader is applied on the embodiments described with reference to FIG. 12.

Referring to FIG. 16, a heat spreader 1626 has a plate portion 1626a and an engaging portion 1626b formed with trenches TR, as similar to the heat spreader 1226 described with reference to FIG. 12. In addition, the heat spreader 1626 further has a sidewall portion 1626c extending downwardly from the plate portion 1626a and laterally surrounding the package substrate 118 as well as the components disposed on the package substrate 118. The package structure including the package substrate 118 and the components disposed thereon is located in a cavity defined by the plate portion 1626a, the engaging portion 1626b and the sidewall portion 1626c of the heat spreader 1626. Additional trenches TR′ may be formed in the sidewall portion 1626c, for further increasing heat exchange area. The trenches TR extending into the plate portion 1626a and the engaging portion 1626b are formed at a side of the plate portion 1626a facing away from the engaging portion 1626b and the sidewall portion 1626c, whereas the trenches TR′ extending into the sidewall portion 1626c are formed at a side of the sidewall portion 1626c facing away from the plate portion 1626a. In some embodiments, the trenches TR′ are deeper than the trenches TR.

Further, in some embodiments where the semiconductor package module 1600 is designed to be compatible with a two-phase immersion cooling apparatus (e.g., the immersion cooling apparatus 160 as shown in FIG. 1B), the heat spreader 1626 may be conformally coated with one or more layers of wicking structure 1640. The wicking structure 1640 may include a porous layer or include microstructures (e.g., mesh, bumps etc.), as similar to the wicking structure 140 described with reference to FIG. 1C. In some embodiments, the wicking structure 1640 conformally covers the sides of the heat spreader 1626 formed with the trenches TR, TR′. Alternatively, all of the surfaces of the heat spreader 1626 in contact with the dielectric cooling liquid 164 (as shown in FIG. 1B) are coated with the wicking structure 1640.

Although not shown, the plate portion 1626 of the heat spreader 1626 is fastened to the ring structure 134 by screws, as similar to the embodiments described with reference to FIG. 1C, FIG. 3, FIG. 5, FIG. 6, FIG. 9 and FIG. 10. Further, an attach stopper may be formed between the ring structure 134 and the heat spreader 1626, as similar to the embodiments described with reference to FIG. 9. In addition, the plate portion 1626a of the heat spreader 1626 may be further supported by a seal dam, as similar to the embodiments described with reference to FIG. 10. Alternatively, as similar to the embodiments described with reference to FIG. 11, FIG. 13, FIG. 14, FIG. 15 the plate portion 1626a of the heat spreader 1626 may be attached to a ring structure having a wall portion and a laterally extending portion, and the engaging portion 1626b of the heat spreader 1626 may be laterally recessed with respect to the thermal interfacial structure TM. Moreover, as described with reference to FIG. 14 and FIG. 15, variations to the engaging portion of a heat spreader may be applied to the heat spreader 1626.

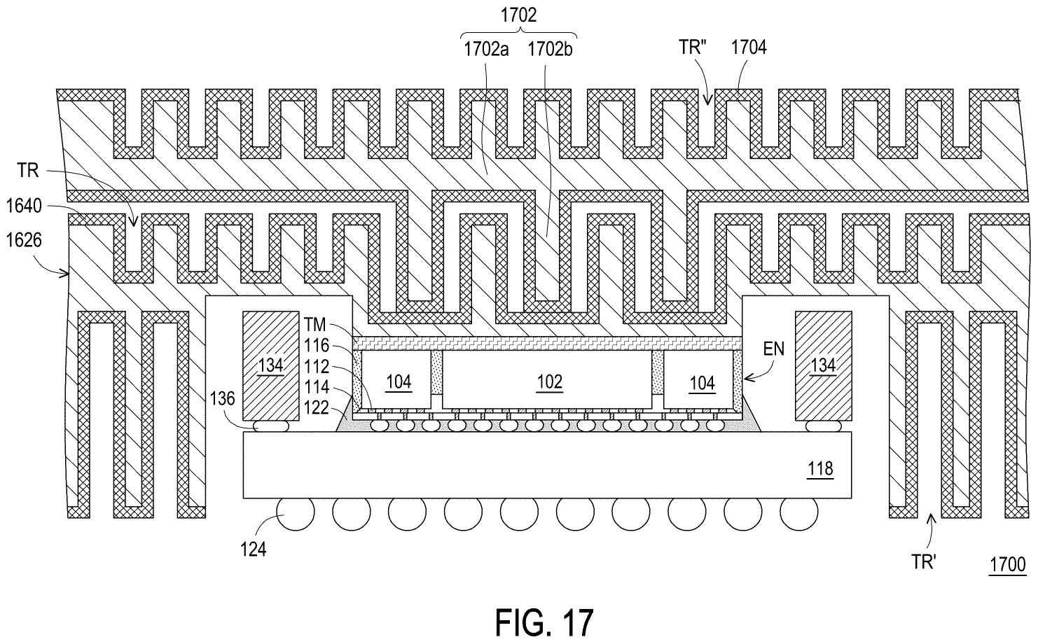

FIG. 17 is a schematic cross-sectional view illustrating a semiconductor package module 1700, according to some embodiments of the present disclosure. As will be described, variations could be further applied on the embodiments described with reference to FIG. 16.

Referring to FIG. 17, an additional heat spreader 1702 is placed on the heat spreader 1626. The additional heat spreader 1702 is similar to the heat spreaders according to various embodiments in terms of function and material. As a difference from other heat spreaders described above, the additional heat spreader 1702 has a plate portion 1702a and multiple protruding portions 1702b. The plate portion 1702a laterally spans over the heat spreader 1626. The supporting portions 1702 vertically extend away from the plate portion 1702a, and may be inserted into the trenches TR extending in the plate portion 1626a and the engaging portion 1626b of the heat spreader 1626. In some embodiments, those trenches TR inserted with the protruding portions 1702b of the heat spreader 1702 may be larger in size (e.g., depth and width), as compared to other trenches TR. Further, in some embodiments, the protruding portions 1702b of the heat spreader 1702 may have a height greater than a depth of those trenches TR accommodating the protruding portions 1702b of the additional heat spreader 1702, such that the plate portion 1702a of the additional heat spreader 1702 can be lifted over the heat spreader 1626. Moreover, although not shown, the additional heat spreader 1702 may be attached to the heat spreader 1626 via solder joints or thermally conductive interface material.

According to some embodiments, trenches TR″ are formed at a side of the plate portion 1702a of the additional heat spreader 1702 facing away from the heat spreader 1626. Moreover, in some embodiments where the semiconductor package module 1700 is designed to be compatible with a two-phase immersion cooling apparatus (e.g., the immersion cooling apparatus 160 as shown in FIG. 1B), the additional heat spreader 1702 may be conformally coated with one or more layers of wicking structure 1704. As similar to the wicking structure 140 described with reference to FIG. 1C, the wicking structure 1704 may include a porous layer or include microstructures (e.g., mesh, bumps etc.). As an example, all of the surfaces of the additional heat spreader 1702 in contact with the dielectric cooling liquid 164 (as shown in FIG. 1B) are covered by the wicking structure 1704.

In regarding fabrication of the semiconductor package module 1700, the additional heat spreader 1702 may be placed onto the heat spreader 1626 after the heat spreader 1626 is attached to the thermal interfacial structure TM. Alternatively, the heat spreader 1626 may be attached to the thermal interfacial structure TM with the additional heat spreader 1702 already provided thereon.

In addition, although not illustrated, the heat spreader 1702 may be alternatively implemented in other embodiments. As an example, the heat spreader 1702 may be placed on the heat spreader 1226 as shown in FIG. 12, and some of the trenches TR in the heat spreader 1226 are modified to be inserted with the protruding portions 1702b of the heat spreader 1702. Further, the heat spreader 1702 can be optionally formed with the trenches TR″, and/or coated with the wicking structure 1704.

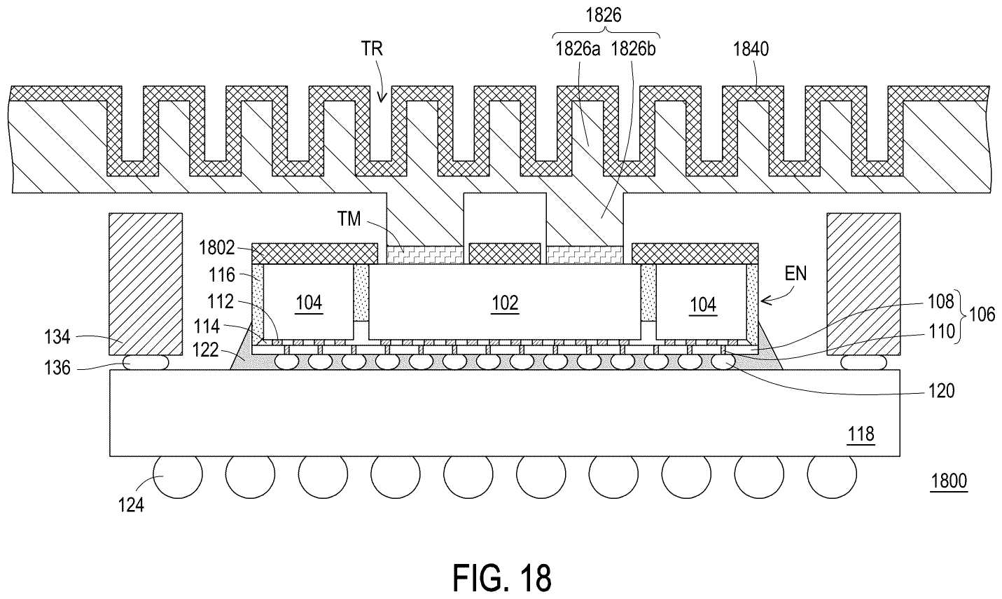

FIG. 18 is a schematic cross-sectional view illustrating a semiconductor package module 1800, according to some embodiments of the present disclosure. Variations to the heat spreader and the thermal interfacial structure will be described, and such variations are applicable to other embodiments described in the present disclosure.

Referring to FIG. 18, the thermal interfacial structure TM is formed as separate patterns, which are in contact with hot spots in the encapsulated structure EN. As an example, the hot spots can be processor cores in the SOC device die 102, but the present disclosure is not limited thereto. Further, a heat spreader 1826 attached to the encapsulated structure EN has a plat portion 1826a and separate engaging portions 1826b vertically extending from the plate portion 1826a and in contact with the encapsulated structure EN through the patterns of the thermal interfacial structure TM. The heat spreader 1826 is similar to the heat spreaders described with various embodiments in terms of function and material. Although not shown, the plate portion 1826a of the heat spreader 1826 may be fastened to the ring structure 134 by screws, as similar to the embodiments described with reference to FIG. 1C, FIG. 3, FIG. 5, FIG. 6, FIG. 9 and FIG. 10. Further, an attach stopper may be formed between the ring structure 134 and the heat spreader 1826, as similar to the embodiments described with reference to FIG. 9. In addition, the plate portion 1826a of the heat spreader 1826 may be further supported by a seal dam, as similar to the embodiments described with reference to FIG. 10. Alternatively, as similar to the embodiments described with reference to FIG. 11, FIG. 13, FIG. 14, FIG. 15 the plate portion 1826a of the heat spreader 1826 may be attached to a ring structure having a wall portion and a laterally extending portion.

Since a back surface of the encapsulated structure EN is partially covered by the thermal interfacial structure TM and the engaging portions 1826b of the heat spreader 1826, some portions of the encapsulated structure EN are not in contact with the thermal interfacial structure TM and the heat spreader 1826, and mechanical interaction between the encapsulated structure EN and the heat spreader 1826 can be reduced. According to some embodiments where the semiconductor package module 1800 is designed to be compatible with a two-phase immersion cooling apparatus (e.g., the immersion cooling apparatus 160 as shown in FIG. 1B), these portions of the encapsulated structure EN (not covered by the thermal interfacial structure TM and the engaging portions 1826b of the heat spreader 1826) may be covered by one or more layers of wicking structure 1802. In these embodiments, these portions of the encapsulated structure EN (not covered by the thermal interfacial structure TM and the engaging portions 1826b of the heat spreader 1826) are in contact with the dielectric cooling liquid 164 (as shown in FIG. 1B) through the wicking structure 1802. As similar to the wicking structure 140 as described with reference to FIG. 1C, the wicking structure 1802 may include a porous layer or include microstructures (e.g., mesh, bumps etc.). In addition, the wicking structure 1802 may be formed at a side of the encapsulated structure EN facing away from the package substrate 118, and may be at least in contact with the device die 102 and the die stacks 104.

Furthermore, trenches TR may be formed at a side of the plate portion 1826a facing away from the encapsulated structure EN, for increasing heat exchange area. In some embodiments, the trenches TR are confined in the plate portion 1826a, and may not further extend to the engaging portions 1826b, even for some of the trenches TR within regions of the heat spreader 1826 where the plate portion 1826a and the engaging portions 1826b are overlapped. In alternative embodiments, the trenches TR within the regions (where the plate portion 1826a and the engaging portions 1826b are overlapped) further extend to the engaging portions 1826b. Moreover, in some embodiments where the semiconductor package module 1800 is designed to be compatible with a two-phase immersion cooling apparatus (e.g., the immersion cooling apparatus 160 as shown in FIG. 1B), the heat spreader 1826 may be conformally coated with one or more layers of wicking structure 1840. The wicking structure 1840 may include a porous layer or include microstructures (e.g., mesh, bumps etc.), as similar to the wicking structure 140 described with reference to FIG. 1C. In some embodiments, the wicking structure 1840 covers the side of the heat spreader 1826 formed with the trenches TR. In other embodiments, all of the surfaces of the heat spreader 1826 in contact with the dielectric cooling liquid 164 (as shown in FIG. 1B) are coated with the wicking structure 1840.

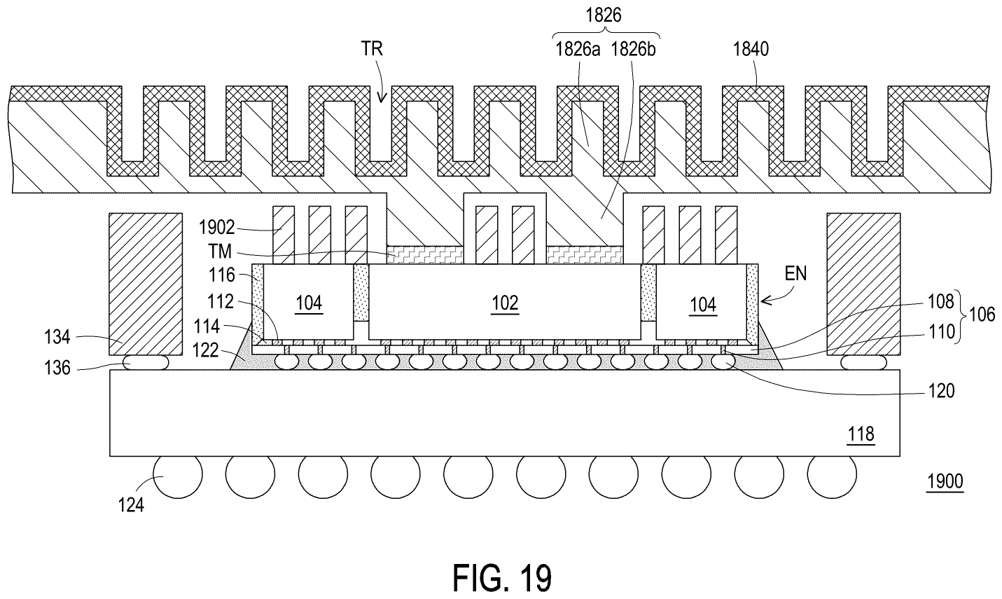

FIG. 19 is a schematic cross-sectional view illustrating a semiconductor package module 1900, according to some embodiments of the present disclosure. A variation to the embodiments described with reference to FIG. 18 will be discussed.

Referring to FIG. 19, the portions of the encapsulated structure EN not covered by the thermal interfacial structure TM and the engaging portions 1826b of the heat spreader 1826 are placed with conductive pillars 1902, rather than being covered by the wicking structure 1802. The conductive pillars 1902 separately stand on the encapsulated structure EN, and are disposed around the patterns of the thermal interfacial structure TM and the engaging portions 1826b of the heat spreader 1826. The device die 102 and the die stacks 104 in the encapsulated structure EN may be in contact with the conductive pillars 1902, and heat generated from the device die 102 and the die stacks 104 can be dissipated to the dielectric cooling liquid 164 (as shown in FIG. 1B) through the conductive pillars 1902. As an example, the conductive pillars 1902 may be formed of copper, silver-diamond, copper-diamond, or combinations thereof.

In regarding fabrication of the semiconductor package module 1900, the conductive pillars 1902 may be disposed on the encapsulated structure EN before the heat spreader 1826 is attached onto the patterns of the thermal interfacial structure TM.

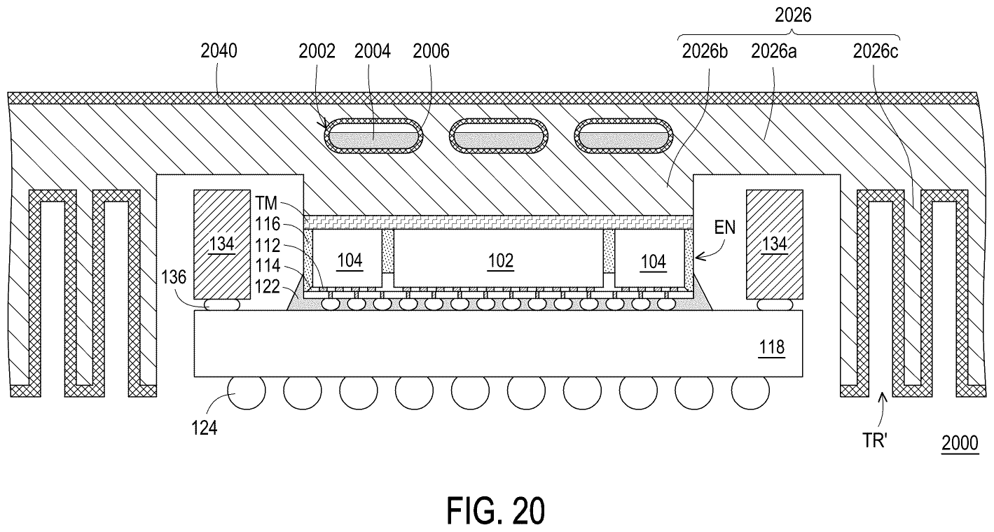

FIG. 20 is a schematic cross-sectional view illustrating a semiconductor package module 2000, according to some embodiments of the present disclosure. A variation to the heat spreader will be described, and such variation is applicable to other embodiments described in the present disclosure.

Referring to FIG. 20, the encapsulated structure EN is thermally coupled to a heat spreader 2026. The heat spreader 2026 has a plate portion 2026a laterally spanning over the encapsulated structure EN, and has an engaging portion 2026b extending from the plate portion 2026a and in contact with the encapsulated structure EN through the thermal interfacial structure TM, as similar to the heat spreaders described with various embodiments. As a difference from other heat spreaders, pipes 2002 are formed in the plate portion 2026a of the heat spreader 2026, and cooling liquid 2004 may be filled in the pipes 2002. The pipes 2002 may be closed pipes, and the cooling liquid 2004 may be sealed in the pipes 2002. The cooling liquid 2004 may be vaporized by the thermal energy generated from the encapsulated structure EN and transferred through the heat spreader 2026. Accordingly, the thermal energy carried by the heat spreader 2026 can not only be dissipated through the external cooling apparatus (e.g., the immersion cooling apparatus 160 as shown in FIG. 1B), but also dissipated via the cooling liquid 2004 sealed in the heat spreader 2026. In some embodiments, the pipes 2002 are positioned over the encapsulated structure EN, to facilitate dissipation of the heat came from the encapsulated structure EN. In these embodiments, the pipes 2002 may overlap the encapsulated structure EN. Once the heat spreader 2026 is cooled down, the cooling liquid 2004 in gas state may return to liquid state, and circulation of the cooling liquid 2004 is performed in each of the pipes 2002. In some embodiments, considering volume expansion resulted from vaporization, each of the pipes 2002 is not filled up by the cooling liquid 2004. Further, in some embodiments, inner surfaces of the pipes 2002 are each coated with one or multiple layers of wicking structure 2006. The wicking structure 2006 may include a porous layer or include microstructures (e.g., mesh, bumps etc.), as similar to the wicking structure 140 described with reference to FIG. 1C.

In some embodiments, the heat spreader 2026 further has a sidewall portion 2026c extending downwardly from the plate portion 2026a and laterally surrounding the package substrate 118 as well as the components disposed on the package substrate 118. The package structure including the package substrate 118 and the components disposed thereon is located in a cavity defined by the plate portion 2026a, the engaging portion 2026b and the sidewall portion 2026c of the heat spreader 2026. In some embodiments, trenches TR′ may be formed at a side of the sidewall portion 1626c facing away from the plate portion 2026a. Furthermore, in some embodiments where the semiconductor package module 2000 is designed to be compatible with a two-phase immersion cooling apparatus (e.g., the immersion cooling apparatus 160 as shown in FIG. 1B), the heat spreader 2026 may be conformally coated with one or more layers of wicking structure 2040. The wicking structure 2040 may include a porous layer or include microstructures (e.g., mesh, bumps etc.), as similar to the wicking structure 140 described with reference to FIG. 1C. A side of the plate portion 2026a of the heat spreader 2026 facing away from the encapsulated structure EN is coated with the wicking structure 2040. In those embodiments where the heat spreader 2026 further has the sidewall portion 2026c formed with the trenches TR′, the side of the sidewall portion 2026c formed with the trenches TR′ may be coated with the wicking structure 2040 as well.

Although not shown, the plate portion 2026a of the heat spreader 2026 may be fastened to the ring structure 134 by screws, as similar to the embodiments described with reference to FIG. 1C, FIG. 3, FIG. 5, FIG. 6, FIG. 9 and FIG. 10. Further, an attach stopper may be formed between the ring structure 134 and the heat spreader 2026, as similar to the embodiments described with reference to FIG. 9. In addition, the plate portion 1826a of the heat spreader 1826 may be further supported by a seal dam, as similar to the embodiments described with reference to FIG. 10. Alternatively, as similar to the embodiments described with reference to FIG. 11, FIG. 13, FIG. 14, FIG. 15 the plate portion 2026a of the heat spreader 2026 may be attached to a ring structure having a wall portion and a laterally extending portion, and the engaging portion 2026b of the spreader 2026 may be laterally recessed from the thermal interfacial structure TM.

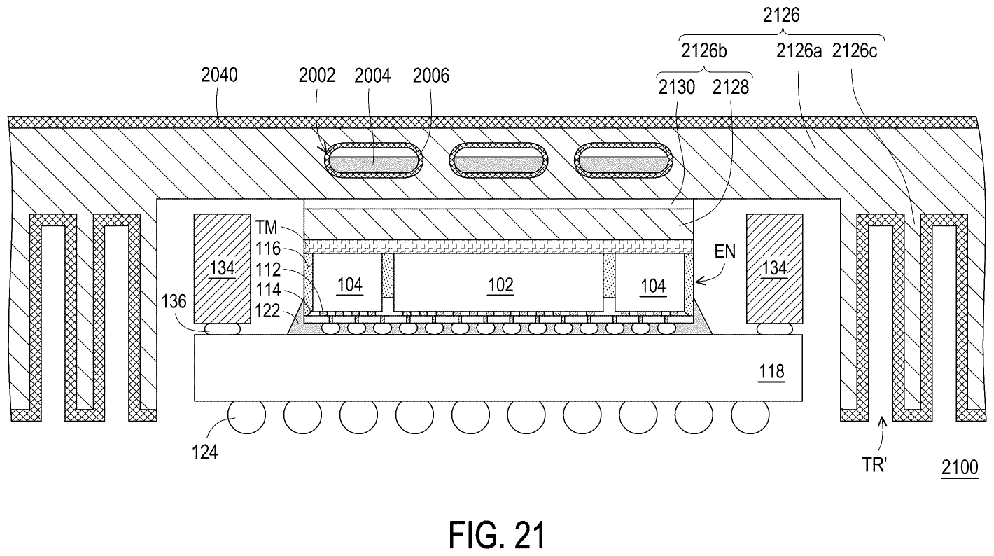

FIG. 21 is a schematic cross-sectional view illustrating a semiconductor package module 2100, according to some embodiments of the present disclosure. As will be described, a variation to the heat spreader described with reference to FIG. 14 and FIG. 15 is further applied on the embodiments described with reference to FIG. 20.

Referring to FIG. 21, a heat spreader 2126 has a plate portion 2126a, an engaging portion 2126b and a sidewall portion 2126c, as similar to the heat spreader 2026 described with reference to FIG. 20. As a difference from the heat spreader 2026, the engaging portion 2126b of the heat spreader 2126 includes a high thermal conductivity lid 2128 in contact with the thermal interfacial structure TM and an adhesion layer 2130 lying between the high thermal conductivity lid 2128 and the plate portion 2126a, which are similar to the high thermal conductivity lid 1428 and the adhesion layer 1430 as described with reference to FIG. 14 and FIG. 15. That is, the engaging portion 2126b may be different from the plate portion 2126a and the sidewall portion 2126c in terms of material.

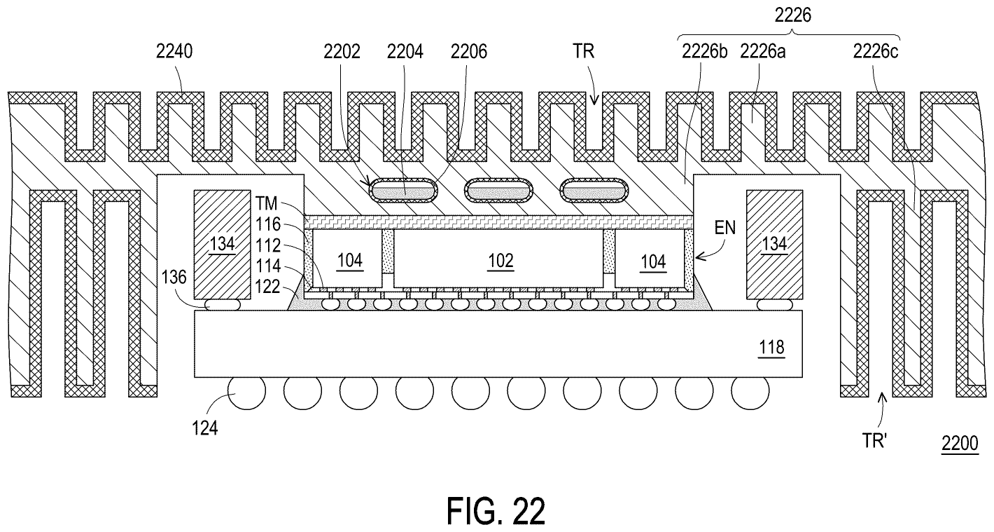

FIG. 22 is a schematic cross-sectional view illustrating a semiconductor package module 2200, according to some embodiments of the present disclosure. A variation to the embodiments described with reference to FIG. 20 will be discussed.

Referring to FIG. 22, a heat spreader 2226 has a plate portion 2226a, an engaging portion 2226b and a sidewall portion 2226c, as similar to the heat spreader 2026 described with reference to FIG. 20. A difference between the heat spreaders 2026, 2226 lies in that pipes 2202 are embedded in the engaging portion 2226b of the heat spreader 2226, rather than being designed in the plate portion 2226a of the heat spreader 2226. As similar to the pipes 2002 described with reference to FIG. 20, the pipes 2202 may be filled with cooling liquid 2204, and may be coated with one or more layers of wicking structure 2206 at inner side. In some embodiments, trenches TR are formed at a side of the plate portion 2226a facing away from the encapsulated structure EN, and trenches TR′ are formed at a side of the sidewall portion 2226c facing away from the plate portion 2226a.

Further, in those embodiments where the semiconductor package module 2200 is designed to be compatible with a two-phase immersion cooling apparatus (e.g., the immersion cooling apparatus 160 as shown in FIG. 1B), the heat spreader 2226 may be conformally coated with one or more layers of wicking structure 2240. The wicking structure 2240 may include a porous layer or include microstructures (e.g., mesh, bumps etc.), as similar to the wicking structure 140 described with reference to FIG. 1C. In some embodiments, the plate portion 2226a of the heat spreader 2026 formed with the trenches TR is coated with the wicking structure 2240. In those embodiments where the heat spreader 2226 further has the sidewall portion 2226c formed with the trenches TR′, the side of the sidewall portion 2226c formed with the trenches TR′ may be coated with the wicking structure 2040 as well.

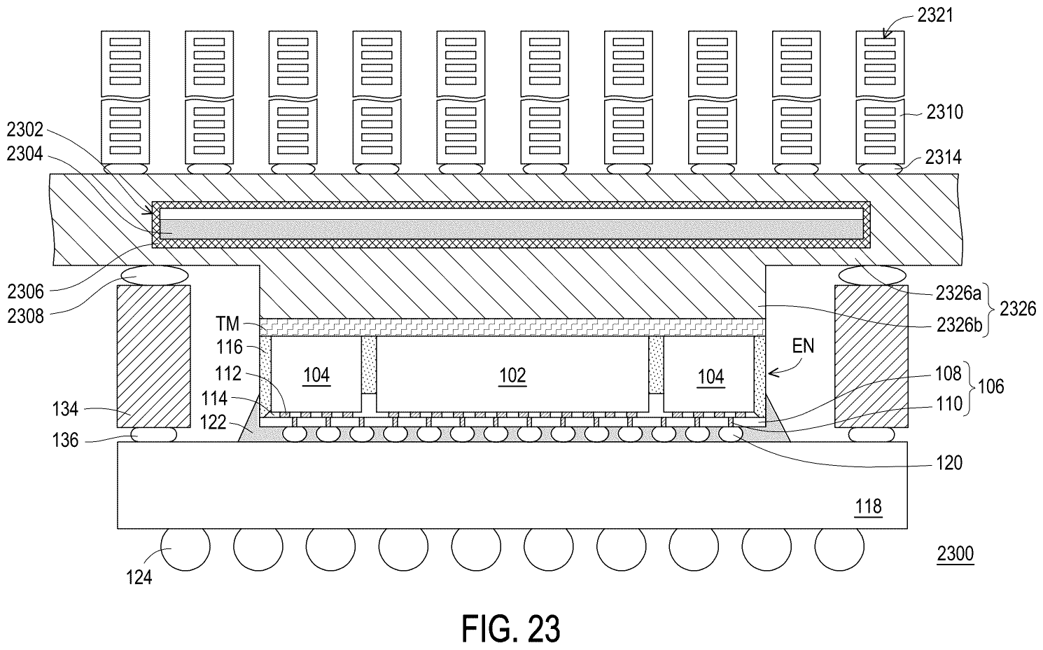

FIG. 23 is a schematic cross-sectional view illustrating a semiconductor package module 2300, according to some embodiments of the present disclosure. Variations to the heat spreader will be described, and such variations are applicable to other embodiments described in the present disclosure.

Referring to FIG. 23, as similar to other heat spreaders described above, a heat spreader 2326 has a plate portion 2326a lying over the thermal interfacial structure TM, and has an engaging portion 2326b extending from the plate portion 2326a and in contact with the thermal interfacial structure TM. Particularly, a sealed chamber 2302 is formed in the plate portion 2326a of the heat spreader 2326. As similar to the pipes 2202, 2202 described above, the sealed chamber 2302 is filled with cooling liquid 2304, and may be coated with one or more layers of wicking structure 2306 at its inner surface. The cooling liquid 2304 may be vaporized by the thermal energy generated from the encapsulated structure EN and transferred through the heat spreader 2326. Accordingly, the thermal energy carried by the heat spreader 2326 can not only be dissipated through the external cooling apparatus (e.g., the immersion cooling apparatus 160 as shown in FIG. 1B), but also dissipated via the cooling liquid 2304 sealed in the heat spreader 2326. Once the heat spreader 2326 is cooled down, the cooling liquid 2304 in gas state may return to liquid state, and circulation of the cooling liquid 2304 is performed in the sealed chamber 2302. As a difference from the pipes 2202, 2202, the sealed chamber 2302 may laterally span to overlap the entire encapsulated structure EN. In addition, in some embodiments, the plate portion 2326a of the heat spreader 2326 is attached to the ring structure 134 through an adhesive 2308, which may be similar to the adhesive 136 described with reference to FIG. 1C or the adhesive 1102 as described with reference to FIG. 11.

In some embodiments, the plate portion 2326a of the heat spreader 2326 is further attached with heat sink plates 2310. The heat sink plates 2310 separately stand on a side of the plate portion 2326a facing away from the encapsulated structure EN. The heat sink plates 2310 may be formed of a conductive material (e.g. copper, aluminum, cobalt, copper coated with nickel), in order to enhance heat dissipation. Further, each of the heat sink plates 2310 has channels 2312 separately arranged along a vertical direction. The channels 2312 laterally penetrate through the heat sink plates 2310, and heat exchange may further take place at inner surfaces of the channels 2312. As heat exchange area is further increased, the thermal energy generated from the encapsulated structure EN can be dissipated more effectively. In some embodiments, the heat sink plates 2310 are attached to the plate portion 2326a of the heat spreader 2326 through adhesives 2314, which may be similar to the adhesive 136 described with reference to FIG. 1C or the adhesive 1102 as described with reference to FIG. 11. Further, in some embodiments, the heat sink plates 2310 have identical height.

In regarding fabrication of the semiconductor package module 2400, the heat sink plates 2310 may be attached to the heat spreader 2326 after the heat spreader 2326 is attached onto the thermal interfacial structure TM and the ring structure 134.

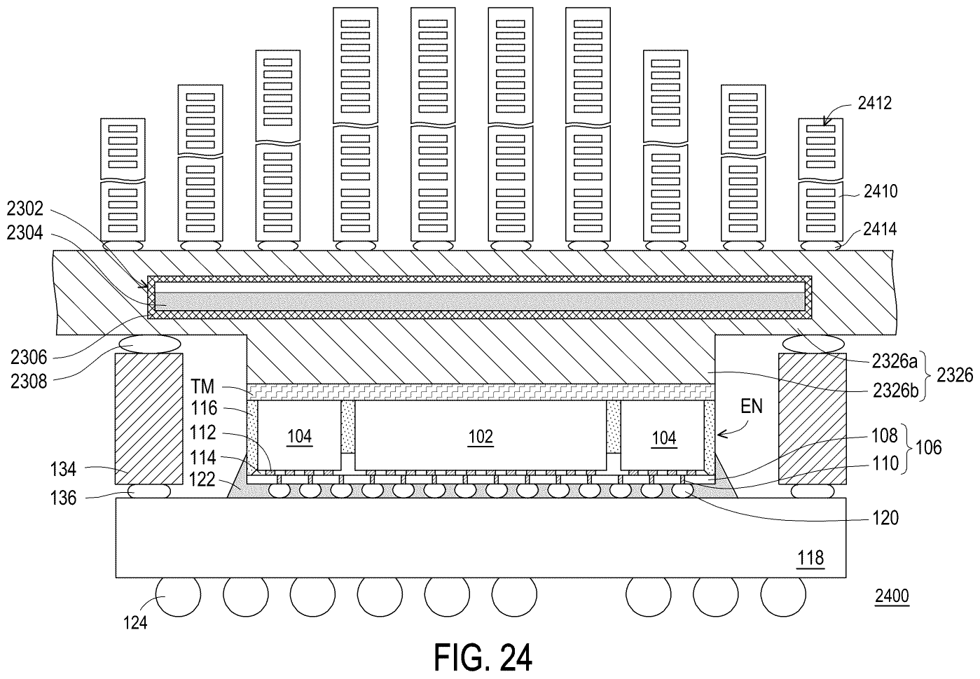

FIG. 24 is a schematic cross-sectional view illustrating a semiconductor package module 2400, according to some embodiments of the present disclosure. A variation to the embodiments described with reference to FIG. 23 will be discussed.

Referring to FIG. 24, the heat spreader 2326 is attached with heat sink plates 2410. As similar to the heat sink plates 2310 as described with reference to FIG. 23, the heat sink plates 2410 may have channels 2412 penetrating therethrough, and may be attached to the heat spreader 2326 by adhesives 2414. As a difference from the heat sink plates 2310, the heat sink plates 2410 may have different heights. In some embodiments, some of the heat sink plates 2410 standing over the encapsulated structure EN are taller than other heat sink plates 2410. Further, the heat sink plates 2410 overlapping hot spots in the encapsulated structure EN may have greatest height.

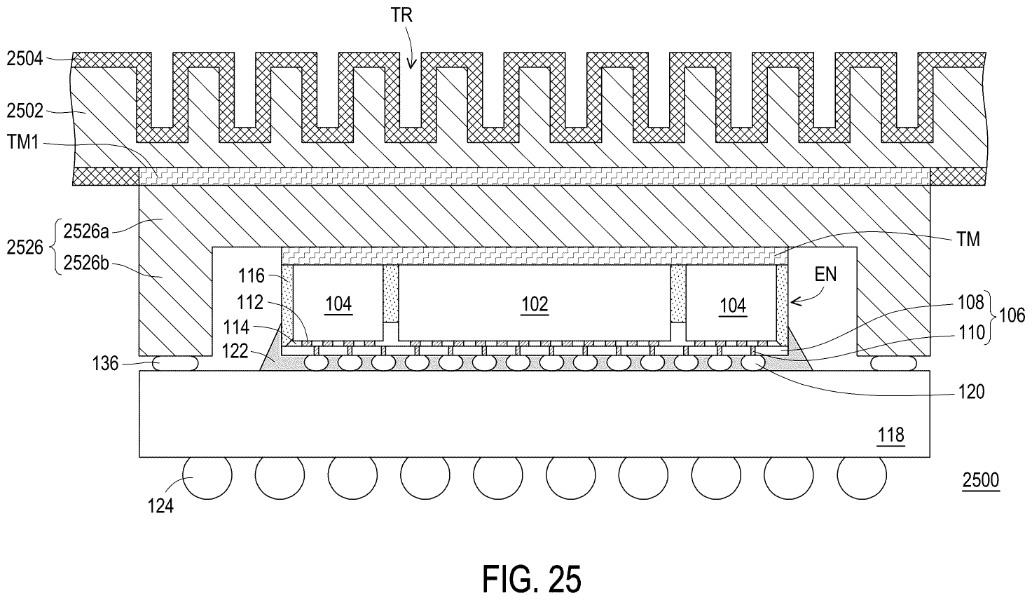

FIG. 25 is a schematic cross-sectional view illustrating a semiconductor package module 2500, according to some embodiments of the present disclosure. As will be described, heat generated from the encapsulated structure EN can be dissipated through alternative heat dissipating components.

Referring to FIG. 25, the encapsulated structure EN is attached with a heat spreader 2526 through the thermal interfacial structure TM. The heat spreader 2526 is similar to other heat spreaders described above (e.g., the heat spreader 126 as shown in FIG. 1C) in terms of function and material. As a difference from other heat spreaders, the heat spreader 2526 has a plate portion 2526a and a supporting portion 2526b. The plate portion 2526a laterally extends over the encapsulated structure EN, and is in contact with the encapsulated structure EN through the thermal interfacial structure TM. The supporting portion 2526b vertically extends from a peripheral region of the plate portion 2526a, and is attached to the package substrate 118 through, for example, the adhesive 136. In some embodiments, the encapsulated structure EN is laterally enclosed by the supporting portion 2526b of the heat spreader 2526.

In some embodiments, an additional heat spreader 2502 is further attached to the heat spreader 2526. The additional heat spreader 2502 is similar to the heat spreader 2526 in terms of function and material, and may laterally extend over the plate portion 2526a of the heat spreader 2526. Further, the additional heat spreader 2502 may be attached to the plate portion 2526a of the heat spreader 2526 through a thermal interfacial structure TM1, which is similar to the thermal interfacial structure TM. In other words, the thermal interfacial structure TM1 can be any one of the composite thermal interfacial layer 128 as shown in FIG. 1C, the composite thermal interfacial layer 328 as shown in FIG. 3 and the composite thermal interfacial layer 528 as shown in FIG. 5, or represents the pillar structures 628 as shown in FIG. 6. In some embodiments, trenches TR are formed at a side of the additional heat spreader 2502 facing away from the heat spreader 2526, to increase heat exchange area.

Moreover, in those embodiments where the semiconductor package module 2500 is designed to be compatible with a two-phase immersion cooling apparatus (e.g., the immersion cooling apparatus 160 as shown in FIG. 1B), the additional heat spreader 2502 may be conformally coated with one or more layer of wicking structure 2504. The wicking structure 2504 may include a porous layer or include microstructures (e.g., mesh, bumps etc.), as similar to the wicking structure 140 described with reference to FIG. 1C. In some embodiments, at least a first side of the additional heat spreader 2502 formed with the trenches TR as well as a second side of the additional heat spreader 2502 facing toward the thermal interfacial structure TM1 are coated with the wicking structure 2504. However, a region of the second side of the additional heat spreader 2502 may be free of the wicking structure 2504, such that the additional heat spreader 2502 can be in direct contact with the thermal interfacial structure TM1, and adhesion between the additional heat spreader 2502 and the thermal interfacial structure TM1 can be ensured.

In regarding fabrication of the semiconductor package module 2500, the additional heat spreader 2502 may be attached onto the heat spreader 2526 through the thermal interfacial structure TM1 by possible processes similar to the processes used for attaching the heat spreader 2526 to the encapsulated structure EN through the thermal interfacial structure TM.

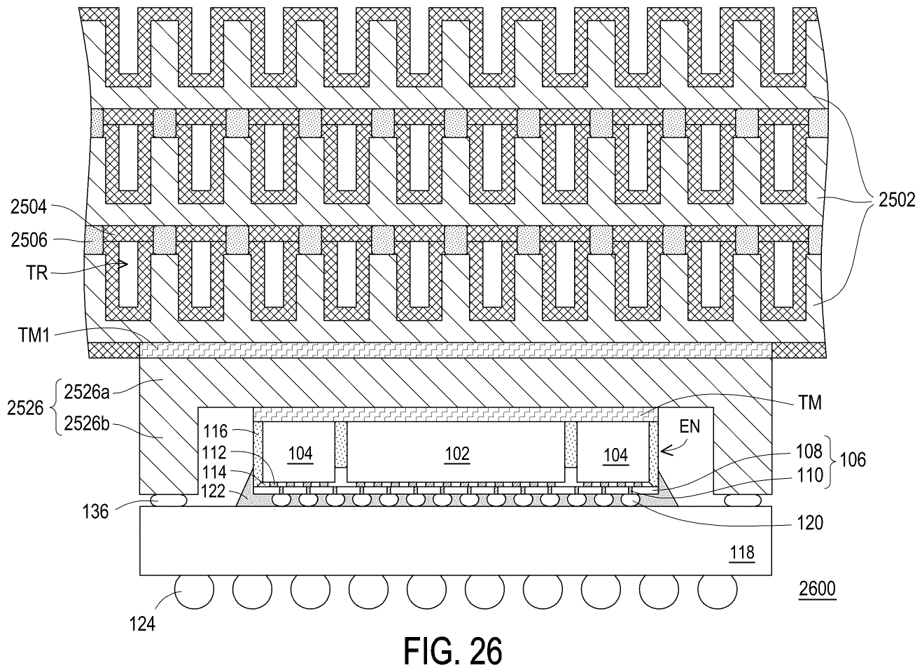

FIG. 26 is a schematic cross-sectional view illustrating a semiconductor package module 2600, according to some embodiments of the present disclosure. A variation to the embodiments described with reference to FIG. 25 will be discussed.

Referring to FIG. 26, a plurality of the additional heat spreaders 2502 (e.g., 3 additional heat spreaders 2502) are stacked on the heat spreader 2526. The bottommost one of the additional heat spreaders 2502 is attached to the heat spreader 2526 through the thermal interfacial structure TM1, as described with reference to FIG. 25. In some embodiments, other additional heat spreaders 2502 may be respectively attached to an underlying one of the additional heat spreaders 2502 by solder joints 2506. In these embodiments, regions of the additional heat spreaders 2502 to be placed with the solder joints 2506 may be free of the wicking structure 2504, such that the solder joints 2506 can be in direct contact with vertically adjacent ones of the additional heat spreaders 2502. In alternative embodiments, a stack of the additional heat spreaders 2526 is built by using a three-dimensional printing technique, and the solder joints 2506 may be omitted.

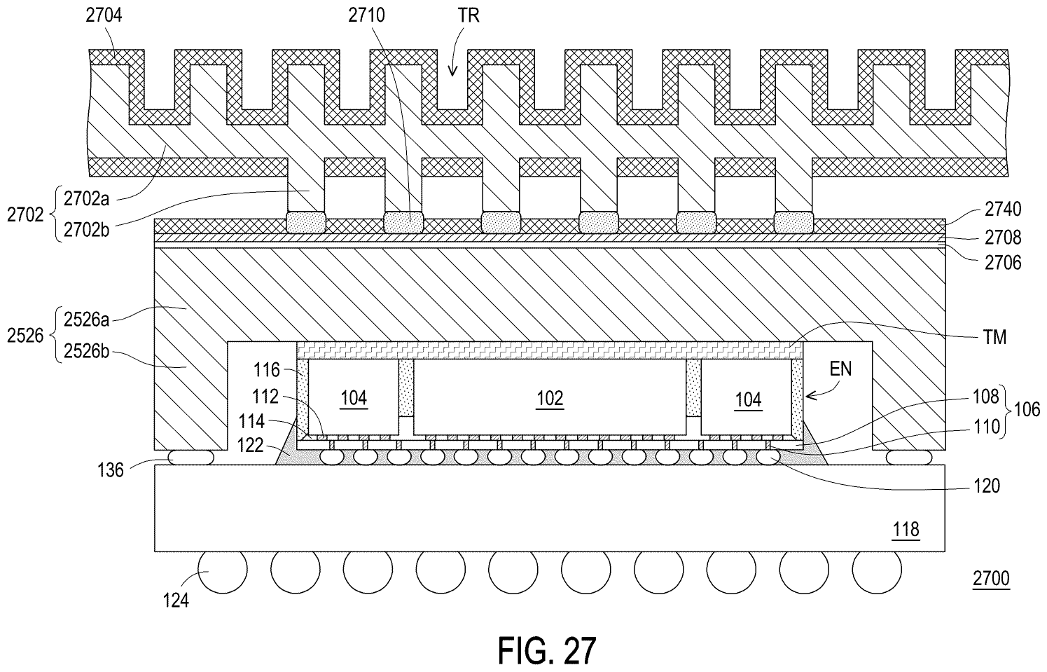

FIG. 27 is a schematic cross-sectional view illustrating a semiconductor package module 2700, according to some embodiments of the present disclosure. Variations to the embodiments described with reference to FIG. 25 will be discussed.

Referring to FIG. 27, an additional heat spreader 2702 is disposed on the heat spreader 2526. The additional heat spreader 2702 is similar to the heat spreader 2526 in terms of function and material. As a difference from the heat spreader 2526, the additional heat spreader 2702 has a plate portion 2702a and multiple protruding portions 2702b. The plate portion 2702a of the additional heat spreader 2702 laterally spans over the plate portion 2526a of the heat spreader 2526. In some embodiments, a side of the plate portion 2702a is formed with trenches TR, for increasing heat exchange area. On the other hand, the protruding portions 2702b of the additional heat spreader 2702 extend toward the heat spreader 2526 from the plate portion 2702a, and stand on the heat spreader 2526 to support the plate portion 2702a. In some embodiments where the semiconductor package module 2700 is designed to be compatible with a two-phase immersion cooling apparatus (e.g., the immersion cooling apparatus 160 as shown in FIG. 1B), the additional heat spreader 2702 may be conformally coated with one or more layer of wicking structure 2704. The wicking structure 2704 may include a porous layer or include microstructures (e.g., mesh, bumps etc.), as similar to the wicking structure 140 described with reference to FIG. 1C. As an example, the heat spreader 2702 may be entirely covered by the wicking structure 2704, except for regions designed to be attached to the heat spreader 2526.

According to some embodiments, an adhesion layer 2706 and a metallic layer 2708 are formed on the heat spreader 2526 before attachment of the additional heat spreader 2702, for improving adhesion between the heat spreader 2526 and the additional heat spreader 2702. The adhesion layer 2706 lies on a side of the heat spreader 2526 facing toward the additional heat spreader 2702, and the metallic layer 2708 is stacked on the adhesion layer 2706. In these embodiments, the protruding portions 2702b may be attached onto the metallic layer 2708 via solder joints 2710. As an example, the adhesion layer 2706 may be formed of a metal alloy including Ti, Cu, Ni, V, Au, the like or combinations thereof, and may be provided on the heat spreader 2526 by a deposition process, such as a sputtering process. In addition, the metallic layer 2708 may be a metal foil (e.g., a copper foil), and may be provided on the adhesion layer 2706 by a lamination process. Moreover, the area size of metallic layer 2708 may be overhanging & larger than the heat spreader 2526 or extended toward surrounding region of heat spreader peripheral sides in order to increase the heat spreading performance.

Further, in some embodiments where the semiconductor package module 2700 is designed to be compatible with a two-phase immersion cooling apparatus (e.g., the immersion cooling apparatus 160 as shown in FIG. 1B), the heat spreader 2526 is further coated with one or more layers of wicking structure 2740. The wicking structure 2740 may include a porous layer or include microstructures (e.g., mesh, bumps etc.), as similar to the wicking structure 140 described with reference to FIG. 1C. In those embodiments where the adhesion layer 2706 and the metallic layer 2708 are provided on the side of the heat spreader 2526 facing toward the additional heat spreader 2702, the wicking structure 2740 may be formed on the metallic layer 2708. The metallic layer 2708 may be entirely covered by the wicking structure 2740, except for the regions designed to be attached to the additional heat spreader 2702.

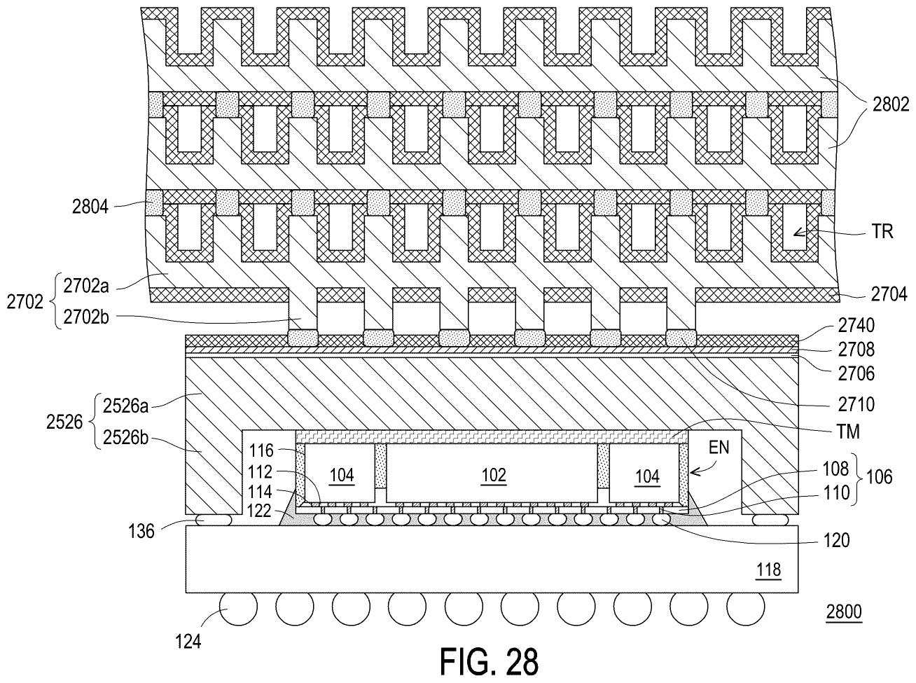

FIG. 28 is a schematic cross-sectional view illustrating a semiconductor package module 2800, according to some embodiments of the present disclosure. A variation to the embodiments described with reference to FIG. 27 will be discussed.

Referring to FIG. 28, other additional heat spreaders 2802 (e.g., 3 additional heat spreaders 2802) are further stacked on the additional heat spreader 2702. The additional heat spreader 2802 is similar to the additional heat spreader 2702, except that the additional heat spreader 2802 may not have protruding portions. That is, the additional heat spreader 2802 may be formed in a plate shape, and optionally formed with trenches TR at a side facing away from the additional heat spreader 2702 and/or coated by one or more layers of wicking structure 2704. In some embodiments, the bottommost one of the additional heat spreaders 2802 is attached to the additional heat spreader 2702 via some solder joints 2804. Similarly, other additional heat spreaders 2802 may be respectively attached to the underlying additional heat spreader 2802 by some other solder joints 2084. In those embodiments where the additional heat spreaders 2702, 2802 are coated with the wicking structure 2704, the wicking structure 2704 may have openings at where the solder joints 2084 are placed. Furthermore, in some embodiments, the additional heat spreaders 2702, 2802 are identical with one another in terms of footprint area.

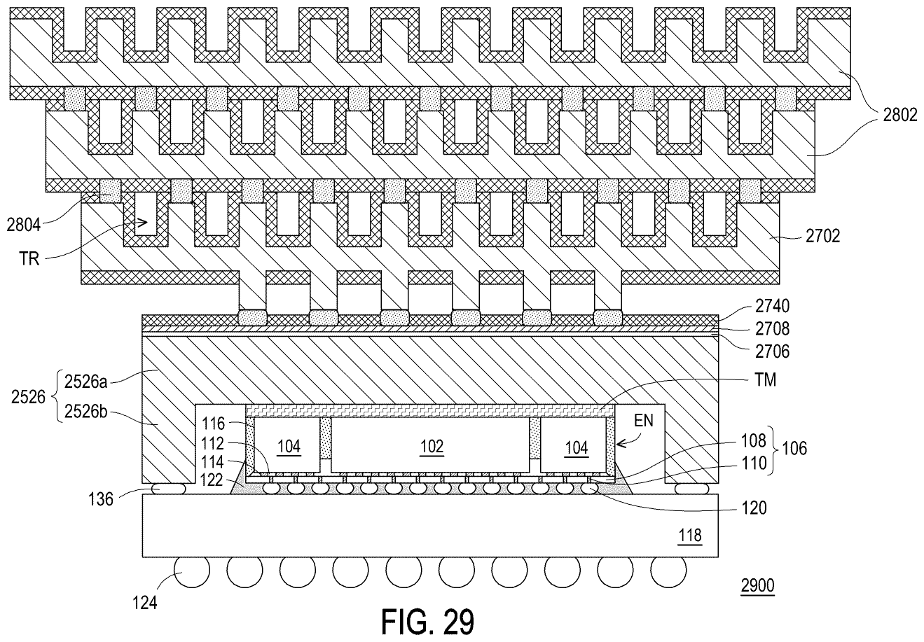

FIG. 29 is a schematic cross-sectional view illustrating a semiconductor package module 2900, according to some embodiments of the present disclosure. A variation to the embodiments described with reference to FIG. 28 will be discussed.

Referring to FIG. 29, according to some embodiments, the additional heat spreaders 2802 are larger than the additional heat spreader 2702 in terms of footprint area. Further, the additional heat spreaders 2802 may respectively have a footprint area greater than a footprint area of the underlying additional heat spreader 2802. In these embodiments, the additional heat spreaders 2702, 2802 may fan out along a direction away from the underlying heat spreader 2526.

As above, embodiments regarding establishing an effective heat dissipation path in each semiconductor package module are described. For illustration purpose, a three-dimensional package structure including the encapsulated structure EN, the interposer 106 and the package substrate 118 is used as an exemplary heat source in each semiconductor package module. The heat source in each semiconductor package module may alternatively be a package structure of another type (e.g., a fan-out package structure). The present disclosure is not limited to the heat source in the semiconductor package module.

According to various embodiments, the thermal interfacial structure with significantly improved thermal conductivity is used in thermal dissipation components designed for conducting heat out of the semiconductor package module. By having superior heat dissipation efficiency, such design may be suitable for more advanced applications that have greater package dimensions and require extreme high power (800 W or beyond). In addition, according to some embodiments, the heat spreader or a stack of heat spreaders in the semiconductor package module is designed with maximized heat exchange area and/or internal circulation, to further improve heat dissipation efficiency. Furthermore, in certain embodiments, surfaces of the heat spreader(s) in the semiconductor package module are further modified to be provide improved heat exchange efficiency in an immersion cooling system.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an aspect of the present disclosure, a semiconductor package module is provided. The semiconductor package module comprises: an encapsulated structure, comprising a device die and an encapsulant laterally enclosing the device die; a package substrate, attached to a first side of the encapsulated structure; a composite thermal interfacial structure, disposed on a second side of the encapsulated structure, and comprising thermally conductive elements arranged side by side or stacked along a vertical direction; a ring structure, attached to the package substrate and laterally surrounding the encapsulated structure; and a heat spreader, attached to the second side of the encapsulated structure through the composite thermal interfacial structure, and supported by the ring structure.

In another aspect of the present disclosure, a semiconductor package module is provided. The semiconductor package module comprises: a semiconductor package; a package substrate, attached to a first side of the semiconductor package; a composite thermal interfacial structure, disposed on a second side of the semiconductor package, and comprising thermally conductive elements arranged side by side or stacked along a vertical direction; a ring structure, attached to the package substrate and laterally surrounding the semiconductor package; and a heat spreader, having a plate portion lying over the composite thermal interfacial structure and supported by the ring structure, and having an engaging portion extending from the plate portion and attached to the composite thermal interfacial structure.

In yet another aspect of the present disclosure, an electronic apparatus is provided. The electronic apparatus comprises: an electronic system, comprising a printed circuit board and a semiconductor package module attached to the printed circuit board; and a tank, accommodating the electronic system and filled with dielectric cooling liquid, wherein the electronic system is submerged in a bath of the dielectric cooling liquid. The semiconductor package module comprises: a semiconductor package; a package substrate, attached to a first side of the semiconductor package; a composite thermal interfacial structure, disposed on a second side of the semiconductor package, and comprising thermally conductive elements arranged side by side or stacked along a vertical direction; a ring structure, attached to the package substrate and laterally surrounding the semiconductor package; and a heat spreader, attached to the second side of the semiconductor package through the composite thermal interfacial structure, and supported by the ring structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package module, comprising:
an encapsulated structure, comprising a device die and an encapsulant laterally enclosing the device die;
a package substrate, attached to a first side of the encapsulated structure;
a composite thermal interfacial structure, disposed on a second side of the encapsulated structure, and comprising thermally conductive elements arranged side by side or stacked along a vertical direction;
a ring structure, attached to the package substrate and laterally surrounding the encapsulated structure; and
a heat spreader, attached to the second side of the encapsulated structure through the composite thermal interfacial structure, supported by the ring structure, and having a pipe with a cooling liquid therein.

2. The semiconductor package module according to claim 1, wherein the composite thermal interfacial structure comprises a metallic layer and a gel thermal interfacial material (TIM) laterally enclosing the metallic layer.

3. The semiconductor package module according to claim 2, wherein the composite thermal interfacial structure further comprises a first adhesion layer and a second adhesion layer, the metallic layer and the gel TIM are sandwiched between the first and second adhesion layers, and the first and second adhesion layers are respectively formed of a conductive material.

4. The semiconductor package module according to claim 1, wherein the composite thermal interfacial structure comprises a metallic TIM, a first adhesion layer and a second adhesion layer, the first and second adhesion layers are respectively formed of a conductive material, the metallic TIM is attached to the encapsulated structure through the first adhesion layer, and attached to the heat spreader through the second adhesion layer.

5. The semiconductor package module according to claim 1, wherein the composite thermal interfacial structure comprises laterally separated pillar structures respectively comprising a conductive pillar and solder joints attaching terminals of the conductive pillar to the encapsulated structure and the heat spreader.

6. The semiconductor package module according to claim 1, wherein the composite thermal interfacial structure spans across the entire second side of the encapsulated structure.

7. The semiconductor package module according to claim 1, wherein the heat spreader has a plate portion laterally spanning over the encapsulated structure, an engaging portion located under the plate portion and attached to the composite thermal interfacial structure, and a sidewall portion extending from the plate portion and laterally surrounding the semiconductor package, and the pipe is in the plate portion.

8. The semiconductor package module according to claim 7, wherein trenches are in the sidewall portion.

9. A semiconductor package module, comprising:
a semiconductor package;
a package substrate, attached to a first side of the semiconductor package;
a composite thermal interfacial structure, disposed on a second side of the semiconductor package, and comprising thermally conductive elements arranged side by side or stacked along a vertical direction;
a ring structure, attached to the package substrate and laterally surrounding the semiconductor package;
a heat spreader, having a plate portion lying over the composite thermal interfacial structure and supported by the ring structure, and having an engaging portion extending from the plate portion and attached to the composite thermal interfacial structure; and
pipes located in the plate portion of the heat spreader, wherein a cooling liquid 2004 is sealed in the pipes.

10. The semiconductor package module according to claim 9, wherein the semiconductor package is entirely covered by the engaging portion of the heat spreader.

11. The semiconductor package module according to claim 9, wherein the engaging portion and the plate portion of the heat spreader are formed of different materials, the engaging portion comprises a high thermal conductivity lid and an adhesion layer, the high thermal conductivity lid is attached to the composite thermal interfacial structure, and the adhesion layer lies between the high thermal conductivity lid and the plate portion of the heat spreader.

12. The semiconductor package module according to claim 9, wherein the heat spreader further has a sidewall portion extending from the plate portion and laterally surrounding the semiconductor package and the package substrate.

13. The semiconductor package module according to claim 12, wherein trenches are formed at a side of the sidewall portion facing away from the plate portion.

14. The semiconductor package module according to claim 13, wherein the side of the sidewall portion is coated with one or more layers of wicking structure.

15. The semiconductor package module according to claim 9, wherein the plate portion of the heat spreader is coated with one or more layers of wicking structure.

16. The semiconductor package module according to claim 9, wherein inner surfaces of the pipes are each coated with one or multiple layers of wicking structure.

17. The semiconductor package module according to claim 9, wherein the ring structure is attached to the package substrate through an adhesive.

18. The semiconductor package module according to claim 9, further comprising electrical connectors disposed at a side of the package substrate facing away from the semiconductor package.

19. An electronic apparatus, comprising:
an electronic system, comprising a printed circuit board and a semiconductor package module attached to the printed circuit board, wherein the semiconductor package module comprises:
a semiconductor package;
a package substrate, attached to a first side of the semiconductor package;
a composite thermal interfacial structure, disposed on a second side of the semiconductor package, and comprising thermally conductive elements arranged side by side or stacked along a vertical direction;
a ring structure, attached to the package substrate and laterally surrounding the semiconductor package; and
a heat spreader, attached to the second side of the semiconductor package through the composite thermal interfacial structure, supported by the ring structure, and having pipes with a cooling liquid therein; and
a tank, accommodating the electronic system and filled with dielectric cooling liquid, wherein the electronic system is submerged in a bath of the dielectric cooling liquid.

20. The electronic apparatus according to claim 18, further comprising a condenser, lying over the bath of the dielectric cooling liquid.
